(19) United States
(12) Patent Application Publication
(10) Pub. No.: US 2026/0291466 A1
(43) Pub. Date: Sep. 24, 2026

(54) TUNABLE SUPERCONDUCTING FILTERS

(71) Applicant: 1372934 B.C. LTD., Burnaby (CA)

(72) Inventor: George E. G. Sterling, Vancouver (CA)

(21) Appl. No.: 18/874,200

(22) PCT Filed: Jun. 21, 2023
(86) PCT No.: PCT/US2023/068780

§ 371 Date: Dec. 12, 2024

Related U.S. Application Data
(60) Provisional application No. 63/354,564, filed on Jun. 22, 2022.

(51) Int. Cl. H03H 11/04

(52) U.S. Cl. CPC H03H 11/04

(57) ABSTRACT

A tunable filter can be used to shift a passband of allowable frequencies travelling along a microwave transmission line to a superconducting device in a cryogenic environment, and is formed of materials that superconduct at and below a critical temperature. The tunable filter includes several tunable resonators capacitively coupled to the transmission line, each including a fixed capacitor and a tunable inductance. Each tunable resonator has a resonant frequency, and the union of their resultant frequency profiles determines an overall passband of the tunable filter. Simultaneous tuning of all the inductive elements through the application of one or more bias signals can shift the overall passband of the tunable filter. The tunable filter provides a time-domain based switching solution that limits energy dissipation. The tunable filter can be used to reduce unwanted noise from reaching the superconducting device or to access a particular device within the superconducting device.

### CROSS-REFERENCE TO RELATED APPLICATIONS

This patent application claims priority of U.S. Patent Application No. 63/354,564, filed on Jun. 22, 2022, the entire disclosure of which is hereby incorporated by reference herein for all purposes.

### FIELD

This disclosure generally relates to filters having a tunable frequency response, and more particularly, to filters having a tunable frequency response that are used for transmitting signals to and/or from superconducting devices.

### BACKGROUND

### Quantum Devices

Quantum devices are structures in which quantum mechanical effects are observable. Quantum devices include circuits in which current transport is dominated by quantum mechanical effects. Such devices include spintronics, and superconducting circuits. Both spin and superconductivity are quantum mechanical phenomena. Quantum devices can be used for measurement instruments, in computing machinery, and the like.

### Hybrid Computing System Comprising a Quantum Processor

A hybrid computing system can include a digital computer communicatively coupled to an analog computer. In some implementations, the analog computer is a quantum computer and the digital computer is a classical computer.

The digital computer can include a digital processor that can be used to perform classical digital processing tasks described in the present systems and methods. The digital computer can include at least one system memory which can be used to store various sets of computer- or processor-readable instructions, application programs and/or data.

The quantum computer can include a quantum processor that includes programmable elements such as qubits, couplers, and other devices. The qubits can be read out via a readout system, and the results communicated to the digital computer. The qubits and the couplers can be controlled by a qubit control system and a coupler control system, respectively. In some implementations, the qubit and the coupler control systems can be used to implement quantum annealing on the analog computer.

### Quantum Processor

A quantum processor may take the form of a superconducting quantum processor. A superconducting quantum processor may include a number of superconducting qubits and associated local bias devices. A superconducting quantum processor may also include couplers (also known as coupling devices) that selectively provide communicative coupling between qubits.

In one implementation, the superconducting qubit includes a superconducting loop interrupted by a Josephson junction. The ratio of the inductance of the Josephson junction to the geometric inductance of the superconducting loop can be expressed as 2πLI_{C}/Φ₀ (where L is the geometric inductance, I_{C} is the critical current of the Josephson junction, and Φ₀ is the flux quantum). The inductance and the critical current can be selected, adjusted, or tuned, to increase the ratio of the inductance of the Josephson junction to the geometric inductance of the superconducting loop, and to cause the qubit to be operable as a bistable device. In some implementations, the ratio of the inductance of the Josephson junction to the geometric inductance of the superconducting loop of a qubit is approximately equal to three.

In one implementation, the superconducting coupler includes a superconducting loop interrupted by a Josephson junction. The inductance and the critical current can be selected, adjusted, or tuned, to decrease the ratio of the inductance of the Josephson junction to the geometric inductance of the superconducting loop, and to cause the coupler to be operable as a monostable device. In some implementations, the ratio of the inductance of the Josephson junction to the geometric inductance of the superconducting loop of a coupler is approximately equal to, or less than, one.

Further details and embodiments of quantum processors that may be used in conjunction with the present systems and devices are described in, for example, U.S. Pat. Nos. 7,533,068; 8,008,942; 8,195,596; 8,190,548; and, 8,421,053.

### Superconducting Processor

A computer processor may take the form of a superconducting processor, where the superconducting processor may not be a quantum processor in the traditional sense. For instance, some embodiments of a superconducting processor may not focus on quantum effects such as quantum tunneling, superposition, and entanglement but may rather operate by emphasizing different principles, such as for example the principles that govern the operation of classical computer processors. However, there may still be certain advantages to the implementation of such superconducting “classical” processors. Due to their natural physical properties, superconducting classical processors may be capable of higher switching speeds and shorter computation times than non-superconducting processors, and therefore it may be more practical to solve certain problems on superconducting classical processors. The present systems and methods are particularly well-suited for use in fabricating both superconducting quantum processors and superconducting classical processors.

### Refrigeration

Temperature is a property that can have a significant impact on the state and evolution of a physical system. For instance, environments of extreme heat can cause even the strongest and most solid materials to melt away or disperse as gas. Likewise, a system that is cooled to cryogenic temperatures may enter into a regime, condition or state where physical properties and behavior differ substantially from what is observed at room temperature. In many technologies, it can be advantageous to operate in this cryogenic regime, condition or state and harness the physical behaviors that are realized in the realm of cold. The various embodiments of the systems, methods and apparatus described herein may be used to provide and maintain the cryogenic environments necessary to take advantage of the physics at cold temperatures. According to the present state of the art, a superconducting material may generally only act as a superconductor if it is cooled below a critical temperature that is characteristic of the specific material in question. For this reason, those of skill in the art will appreciate that a computer system that implements superconducting processors may implicitly include a refrigeration system for cooling the superconducting materials in the system.

Throughout this specification and the appended claims, the term “cryogenic” is used to refer to the temperature range of OK to about 93K. A variety of technologies may be implemented to produce an environment with cryogenic temperature, though a commonly used device that is known in the art is the helium-3-helium-4 dilution refrigerator, known as a dilution refrigerator. Dilution refrigerators can even be used to achieve extreme cryogenic temperatures below 50 mK. In the operation of a typical dilution refrigerator, the apparatus itself requires a background temperature of about 4K. In order to provide this background cooling, the apparatus may be, e.g., immersed in an evaporating bath of liquid helium-4 (⁴He) or, e.g., coupled to another type of refrigeration device, such as a pulse-tube cryocooler. The dilution refrigerator apparatus may comprise a series of heat exchangers and chambers that allow the temperature to be lowered further to a point where a mixture of helium-3 (³He) and ⁴He separates into two distinct phases. The first phase is mostly ³He, known as the concentrated phase, and the second phase is mostly ⁴He with some ³He, known as the dilute phase. The dilution refrigerator apparatus allows some of the ³He to move from the concentrated phase into the dilute phase in an endothermic process analogous to evaporation, providing cooling and allowing a temperature of around 10 mK to be achieved. The ³He is drawn out of the dilute phase mixture through a counter-flow heat exchanger, condensed, cooled, returned to the concentrated phase portion of the mixture via the counter-flow heat exchanger to define a helium circuit. Even though the dilute phase is ⁴He rich, the ³He is preferentially drawn from the dilute phase because ³He has a higher partial pressure than 4He.

In most dilution refrigerator designs, mechanical pumps and compressors, and an external gas-handling system, are used to circulate ³He such that the ³He is warmed from the lowest temperature in the refrigerator up above cryogenic temperatures and towards room temperature before the ³He is returned to the low temperature. The pumps and compressors used are large, expensive, noisy, in need of periodic maintenance, and they inevitably add contaminants, such as air (i.e., nitrogen, oxygen, carbon dioxide, argon, etc.) to the helium. These contaminants typically have higher freezing points than the helium and so may solidify in the helium fluid channels, creating blockages. Such blockages may plug fine capillaries in the dilution refrigerator, causing problems with reliability. Plugging often requires a complete warm-up of a dilution refrigerator in order to remove the contaminants and restore the fridge to normal operations. The procedure of warming and subsequently cooling back down to operating temperatures can take several days. Filters and cold traps can be used to reduce the frequency of plugging by removing contaminants from the helium, but existing filters and traps used in the art are of limited effectiveness. Thus, plugging due to contaminants remains a serious technical challenge in cryogenic refrigeration technology affecting refrigerator performance, and there remains a need in the art for improved systems and methods for contaminant filtering and/or trapping in cryogenic refrigeration systems.

### Electrical Signal Filtration

During transmission, an electrical signal typically comprises a plurality of components each transmitting at a different frequency. The “filtering” or “filtration” of an electrical signal typically involves the selective removal of certain frequencies from the electrical signal during transmission. Such filtration may be accomplished “passively” or “actively.” A passive electrical filter is one that operates without additional power input; that is, the filtration is accomplished by the natural characteristics of the materials or devices through which the electrical signal is transmitted. Passive filters include filters that implement lumped elements such as inductors and capacitors, collectively referred to as lumped element filters (LEFs).

Simple, passive lumped element filters include low-pass and high-pass filters. A low-pass filter is one that substantially filters out higher frequencies and substantially allows lower frequencies to pass through. Conversely, a high-pass filter is one that substantially filters out lower frequencies and substantially allows higher frequencies to pass through. The concepts of low-pass and high-pass filters may be combined to produce “band-pass” filters, which effectively substantially transmit a given range of frequencies and substantially filter out frequencies that fall outside (above and below) of that range. Similarly, “band-stop” filters may be implemented which effectively transmit most frequencies and filter out frequencies that fall inside a given range.

### Shielding and Noise

Magnetic fields produced by external sources may cause unwanted interactions with devices in the integrated circuit. Accordingly, there may be a need for a superconducting shield proximate to devices populating the integrated circuit to reduce the strength of interference such as magnetic and electrical fields.

Superconducting shielding incorporated into an integrated circuit can be used to protect superconducting quantum interference device (SQUID) packages from DC and AC noise, such as magnetic and electrical fields, that would otherwise interfere with operation of the integrated circuit. Regions of the integrated circuit can be unshielded to allow for communication between magnetic and electrical fields external to the SQUID package. An example of this approach is discussed in U.S. Pat. No. 5,173,660.

Superconducting shielding layers may be used in single flux quantum (SFQ) or rapid single flux quantum (RSFQ) technology to separate devices from DC power lines that could otherwise undesirably bias the devices. The devices populate the integrated circuit but are separated from the DC power lines by placing a ground plane between the devices and the DC power line.

In SFQ circuits, ground planes and shielding layers are terminologies used interchangeably. A ground plane in SFQ integrated circuit is a layer of metal that appears to most signals within the circuit as an infinite ground potential. The ground plane helps to reduce noise within the integrated circuit but may be used to ensure that all components within the SFQ integrated circuits have a common potential to compare voltage signals. Contacts can be used between wiring layers and a ground plane throughout SFQ circuitry.

Supercurrent flowing in superconducting wires has an associated magnetic field in the same manner as electrons flowing in normal metal wires. Magnetic fields can couple inductively to superconducting wires, inducing currents to flow. Quantum information processing with superconducting integrated circuits necessarily involves supercurrents moving in wires, and hence associated magnetic fields.

The quantum properties of quantum devices are very sensitive to noise, and stray magnetic fields in superconducting quantum devices can negatively impact the quantum information processing properties of such circuits. Superconducting ground planes have been used in the art to reduce cross-talk between control lines and devices. However, such approaches have only been used in superconducting integrated circuits for classical processing and sensor applications, which are relatively robust against in-circuit noise and operate at significantly higher temperatures as compared with superconducting quantum processing integrated circuits.

In superconducting quantum processing integrated circuits, it is desirable to substantially attenuate and control unwanted cross-talk between devices, otherwise quantum information processing at commercial scales may not be possible. The present methods, systems and apparatus provide techniques for attenuating cross-talk in superconducting quantum processing integrated circuits between quantum devices in order to support the desired quantum effects and controllably couple quantum devices in a manner that permits exchange of coherent quantum information.

### Kinetic Inductance

Current flowing through a metal material in principle stores energy both in the magnetic field of that metal and in the kinetic energy of the charge carriers (e.g., the electrons or Cooper pairs). In non-superconducting metals, the charge carriers collide frequently with the lattice and lose their kinetic energy as Joule heating. This is also referred to as scattering, and quickly releases energy. However, in superconducting materials, scattering is substantially reduced, as the charge carriers are Cooper pairs which are protected against dissipation through scattering. This allows for superconducting materials to store energy in the form of kinetic inductance. This phenomenon allows kinetic inductance to efficiently store energy within the superconducting metal. Kinetic inductance is at least in part determined by the inertial mass of the charge carriers of a given material and increases as carrier density decreases. As the carrier density decreases, a smaller number of carriers must have a proportionally greater velocity in order to produce the same current. Materials that have high kinetic inductance for a given area (as defined below) are referred to as “kinetic inductance materials”, or “high kinetic inductance materials”.

Kinetic inductance materials are those that have a high normal-state resistivity and/or a small superconducting energy gap, resulting in a larger kinetic inductance per unit of area. In general, total inductance L of a superconducting material is given by L=L_{K}+L_{G}, where L_{G} is the geometric inductance and L_{K} is the kinetic inductance. The kinetic inductance of a superconducting film in near-zero temperatures is proportional to the effective penetration depth λ_{eff}. In particular, for a film with a given thickness t, the kinetic inductance of the film is proportional to the ratio of the length of the film L to the width of the film W, where length is in the direction of the current and width is orthogonal to length (note that both width and length are orthogonal to the dimension in which thickness is measured). That is

$${L}_{K} ∼ {λ}_{eff} \frac{L}{W}$$

for a superconducting film with a given thickness. The kinetic inductance fraction of a material is characterized as

$$α = \frac{{L}_{k}}{{L}_{g} + {L}_{k}} .$$

A material considered to have high kinetic inductance would typically have a in the range of 0.1<α≤1. Materials with less than 10% of the energy stored as kinetic inductance would be considered traditional magnetic storage inductors with a small correction.

In some implementations it may be beneficial to attempt to maximize kinetic inductance in minimal volume. This may include attempting to minimize the width of the film, selecting a suitable material with a high effective penetration depth Jeff, and selecting a length for the film which achieves the desired kinetic inductance. It may also be beneficial to attempt to minimize the thickness t of the material, subject to fabrication constraints, as for t<3λ_{eff(bulk)} (where λ_{eff(bulk)} is the effective penetration depth of the material in bulk, not thin-film), λ_{eff} increases at least approximately proportionately to 1/t². In some implementations, t<n·λ_{eff(bulk)}, where n is some value substantially less than 1 (e.g., 0.5, 0.1, 0.05, 0.01, etc.).

Examples of kinetic inductors are discussed in detail in International Patent Publication No. WO2017192733A2. International Patent Publication No. WO2021231224A1 describes further devices utilizing kinetic inductance.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

According to an aspect, there is provided a tunable filter to electrically couple to a transmission line. The tunable filter may include a plurality of tunable resonators, and each one of the plurality of tunable resonators may be comprised of one or more materials that exhibit superconducting behavior at and below respective critical temperatures. Each tunable resonator of the plurality of tunable resonators may include a respective tunable inductance and a respective fixed capacitance to provide a respective resonator frequency response having a respective range of passable frequencies. The tunable filter may have an overall resonator frequency response determined by a union of the ranges of passable frequencies of the resonator frequency responses of a combination of the plurality of tunable resonators, and the overall frequency response may be controllable by selective tuning of the tunable inductances.

In some implementations, each resonator frequency response of a corresponding tunable resonator may provide a respective range of passable frequencies that is non-identical to ranges of passable frequencies that respectively provided by other tunable resonators of the plurality of tunable resonators.

In some implementations, the tunable filter further may include one or more bias lines electrically coupled to the tunable inductances for transmission of respective bias signals to the tunable inductances to selectively tune their respective inductance values.

In some implementations, a first end of the tunable filter may be communicatively coupled to a superconducting device located in a cryogenic environment and a second end of the tunable filter may be communicatively coupled to a computing device located in a region at room temperature. The tunable inductances may be electrically coupled to the superconducting device via the one or more bias lines, and the bias signals transmitted to the tunable inductances are generated by the superconducting device.

In some implementations, a size of the range of passable frequencies of the overall resonator frequency response may be a subset of a communication bandwidth of the superconducting device. The overall resonator frequency response of the tunable filter may be operable to transmit frequencies in a first subset of the communication bandwidth when the bias signals applied to the tunable inductances have a first value, and the overall resonator frequency response of the tunable filter may be operable to transmit frequencies in a second subset of the communication bandwidth when the bias signals applied to the tunable inductances have a second value. The second value may be non-identical to the first value. The second value may be a value between zero and a maximum value, and the second value may determine the frequencies belonging to the second subset.

In some implementations, the tunable filter may enable selective transmission one of a plurality of unique subsets of frequencies of the communication bandwidth of the superconducting device. Each unique subset of frequencies may be operable to enable access to a corresponding one or more unique devices of a plurality of devices within the superconducting device, and each unique device of the plurality of device may be one of: a qubit, a coupler, and a digital-to-analog converter (DAC).

In some implementations, for each tunable resonator of the plurality of tunable resonators: the respective tunable inductance and the respective fixed capacitance are arranged in series with one another, each resonator frequency response includes a resonator passband, and the overall resonator frequency response is a bandpass response provided by a union of the resonator passbands.

In some implementations, for each tunable resonator of the plurality of tunable resonators: the respective tunable inductance and the respective fixed capacitance are arranged in parallel with one another, each resonator frequency response includes a resonator stopband, and the overall resonator frequency response is a band-stop response provided by a union of the resonator stopbands.

In some implementations, the tunable filter may further include a low-pass filter arranged in series with the plurality of tunable resonators, and the low-pass filter may have a low-pass cut-off frequency. A combination of the tunable filter and the low-pass filter may form a switch having: a first switch mode to transmit all frequency content of signals travelling through the switch, in which all the passable frequencies of the overall resonator frequency response fall below the low-pass cut-off frequency; and, a second switch mode to suppress all of the frequency content of the signals travelling through the switch, in which all the passable frequencies of the overall resonator frequency response exceed the low-pass cut-off frequency.

In some implementations, a first end of the tunable filter may be communicatively coupled to a superconducting device and a second end of the tunable filter may be communicatively coupled to a computing device. The tunable inductances may be selectively tuned to switch between the first switch mode and the second switch mode based on a time-domain based bias signal corresponding to an operation cycle of the superconducting device. In the first switch mode, the switch enables electrical communication between the superconducting device and the computing device. In the second switch mode, the switch electrically isolates the superconducting device during noise-sensitive stages of the operation cycle of the superconducting device.

In some implementations, each of the tunable inductances is at least one of: a magnetic flux-biased DC superconducting quantum interference device (SQUID); a current-biased series array of Josephson junctions; a current-biased strip of material having a high kinetic inductance value; and a magnetic flux-biased loop of material having a high kinetic inductance value.

According to another aspect, there is provided a method to shift a frequency range of signals that are transmittable across a transmission line. The method may include transmitting the signals across a tunable filter electrically coupled to the transmission line. The tunable filter may include a plurality of tunable resonators each having a respective tunable inductance and a respective fixed capacitance to provide respective resonator frequency responses. The tunable filter may have an overall resonator frequency response determined by a union of the ranges of passable frequencies of the resonator frequency responses. The plurality of tunable resonators and the transmission line may be comprised of one or more materials that exhibit superconducting behavior at and below respective critical temperatures. The method may include modifying a bias signal based on a tuned passable frequency range. The method may include applying the modified bias signal to each tunable inductance to shift the range of passable frequencies of each tunable resonator, such that the overall frequency response of the tunable filter shifts to enable transmission thereacross of components of the signals within the tuned passable frequency range.

In some implementations, the applying the modified bias signal to each tunable inductance may include transmitting one or more modified bias signals across one or more bias lines that are electrically coupled to the tunable inductances to selectively tune their respective inductance values.

In some implementations, a first end of the transmission line is electrically coupled to a superconducting device that includes a controller. The modifying the bias signal may include: receiving, by the superconducting device, an instruction from a computing device coupled to a second end of the transmission line; determining, by the controller of the superconducting device, the inductance values required of each tunable inductance to shift the range of passable frequencies of each tunable resonator such that the overall resonator frequency response of the tunable filter passes frequencies within the tuned passable frequency range; and generating, by the controller of the superconducting device, the one or more modified bias signals required to tune the tunable inductances to the determined inductance values.

In some implementations, the transmitting the signals across the tunable filter may include transmitting one of a plurality of frequency subsets in a communication bandwidth of the superconducting device across the tunable filter. Prior to the modifying the bias signal, the tunable filter may receive a first bias signal to pass the components of the signals within a first frequency subset of the communication bandwidth, and transmitting the components of the signals within the tuned passable frequency range across the tunable filter includes passing the components of the signals within a second frequency subset of the communication bandwidth through the tunable filter.

In some implementations, the transmitting one of the plurality of frequency subsets across the tunable filter further includes: transmitting signal content having frequencies belonging to a unique frequency subset of the communication bandwidth. The unique frequency subset is to enable access to a respective unique device in the superconducting device, and each unique device is one of: a qubit, a coupler, and a digital-to-analog converter (DAC).

In some implementations, the transmitting the signals across the tunable filter includes transmitting the signals across the plurality of tunable resonators. Each tunable resonator may have the respective tunable inductance and the respective fixed capacitance arranged in series with one another such that each resonator frequency response includes a resonator passband. The overall resonator frequency response may be a bandpass response provided by a union of the resonator passbands.

In some implementations, the transmitting the signals across the tunable filter includes transmitting the signals across the plurality of tunable resonators. Each tunable resonator may have the respective tunable inductance and the respective capacitance arranged in parallel with one another such that each resonator frequency response includes a resonator stopband. The overall resonator frequency response may be a band-stop response provided by a union of the resonator stopbands.

In some implementations, transmitting the signals across the tunable filter arranged on the transmission line may further include transmitting the signals across a low-pass filter arranged in series with the plurality of tunable resonators, and having a low-pass cut-off frequency. The tunable filter and the low-pass filter may form a switch.

In some implementations, prior to modifying the bias signal, the transmitting the signals across the tunable filter may include operating the switch in a first switch mode. The applying the modified bias signal to each tunable inductance to shift the range of passable frequencies of each tunable resonator may include: shifting the overall resonator frequency response of the tunable filter to operate the switch in a second switch mode, and the second switch mode may include transmission of components of the signals within the tuned passable frequency range, The first switch mode and the second switch mode may be different ones of: transmitting all frequency content of the signals through the switch, where all passable frequencies of the overall resonator frequency response fall below the low-pass cut-off frequency; and, suppressing all frequency content of the signals through the switch, where all passable frequencies of the overall resonator frequency response exceed the low-pass cut-off frequency.

In some implementations, a first end of the transmission line is electrically coupled to a superconducting device that includes a controller. The modifying the bias signal may include, generating, by the superconducting device, a time-domain based bias signal corresponding to an operation cycle of the superconducting device, where the time-domain based bias signal selectively tunes the overall resonator frequency response of the tunable resonator to change between operation of the switch in the first switch mode and the second switch mode. Operation of the switch in the first switch mode may enable electrical communication between the superconducting device and a computing device, where the computing device electrically coupled to a second end of the transmission line. Operation of the switch in the second switch mode may electrically isolate the superconducting device during noise-sensitive stages of the operation cycle of the superconducting device.

In some implementations, the applying the modified bias signal to each tunable inductance includes at least one of: applying a bias flux to at least one of: a DC superconducting quantum interference device (SQUID) and a strip of material having a high kinetic inductance value, and applying a bias current to at least one of: a series array of Josephson junctions and a loop of material having a high kinetic inductance value.

In an aspect, there is provided a tunable filter on a transmission line having a first conductor and a second conductor. The tunable filter may include: a plurality of capacitive shunt connections between the first conductor and the second conductor, each capacitive shunt connection forming a respective tunable resonator. The respective tunable resonators may each be configured to have a respective resonance, and the respective resonances may have respective frequency profiles overlapping to form a passband or stopband. The tunable filter may include one or more signal lines connecting to the plurality of tunable resonators to shift the frequency profiles of the respective tunable resonators to move the passband or stopband.

In some implementations, the plurality of tunable resonators each may include a respective capacitor and a respective inductor.

In some implementations, the respective inductors may be tunable inductors.

In some implementations, the tunable inductors may include DC SQUIDs tuned by exposure to a variable magnetic flux via current on the one or more signal lines.

In some implementations, the tunable inductors may include kinetic inductors tuned by exposure to current on the one or more signal lines.

In some implementations, the tunable inductors may include Josephson junction arrays tuned by exposure to current on the one or more signal lines.

In some implementations, the tunable inductors may include kinetic inductance loops tuned by exposure to a variable magnetic flux via current on the one or more signal lines.

In some implementations, the respective capacitors may be in series with the respective inductors, and the passband or stopband may be a passband.

In some implementations, the respective capacitors may be in parallel with the respective inductors, and the capacitive shunt connections may also have respective second capacitors in series with the respective tunable resonators. The passband or stopband may be a stopband.

In some implementations, the first conductor and second conductor are superconductors.

In an aspect, there is provided a switch comprising a tunable filter as described above with a passband or stopband on a transmission line. The passband or stopband of the tunable filter may be tunable to define a Pass state and a Stop state of the switch. A frequency range of interest may be within the passband or outside the stopband in the Pass state, and outside the passband or inside the stopband in the Stop state.

In some implementations, the switch may include one or more additional filters for excluding frequencies outside the frequency range of interest.

In an aspect, there is provided a method of reducing noise in a quantum computer. The method may include: installing on a line carrying input to or output from the quantum computer a switch with a Pass state and a Stop state, as previously described; operating the switch to be in the Pass state during an input/output time period in which input is being sent to or output received from the quantum computer along the line; and, operating the switch to be in the Stop state during a computing time period in which the quantum computer is carrying out computing operations and no input or output is being sent on the line.

In an aspect, there is provided a method of rectifying an alternating current on a superconducting transmission line. The method may include: installing on the transmission line a switch with a Pass state and a Stop state as described above; operating the switch to be in the Pass state during a first time period in which the alternating current is flowing in a first direction along the transmission line; and, operating the switch to be in the Stop state during a second time period in which the alternating current would be, in the absence of the switch, flowing in a second direction opposite to the first direction along the transmission line. The foregoing examples of the related art and limitations related thereto are intended to be illustrative and not exclusive. Other limitations of the related art will become apparent to those of skill in the art upon a reading of the specification and a study of the drawings.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 is a schematic diagram of a hybrid computing system including a digital computer coupled to an analog computer, which employs one or more tunable filters and/or tunable inductors as described herein, in accordance with the present systems, devices, and methods.

FIG. 2 is a schematic is a schematic diagram of a tunable pass-band filter arranged on a transmission line.

FIG. 3 is a graph plotting the frequency response of the tunable passband filter of FIG. 2.

FIG. 4 is a schematic diagram of a tunable stop-band filter arranged on a transmission line.

FIG. 5 is a graph plotting the frequency response of the tunable stop-band filter of FIG. 4.

FIG. 6A is a schematic of a system having a microwave path including an integrated tunable filter to shift a passband of allowable frequencies.

FIG. 6B is a graph illustrating a frequency response of a shift of the passband of allowable frequencies using the system of FIG. 6A.

FIG. 7A is a schematic of a system having a microwave path including an integrated tunable filter operable as a switch.

FIG. 7B is a graph illustrating the frequency response of a signal transmitted through the system of FIG. 7A when used as a switch.

FIG. 8 is a schematic diagram of a tunable inductor comprising a DC SQUID tuned based on an applied flux.

FIG. 9 is a schematic diagram showing a tunable inductor comprising a series of Josephson junctions tuned based on an applied current.

FIG. 10 is a schematic diagram showing a tunable inductor comprising a kinetic inductor tuned based on an applied current.

FIG. 11 is a schematic diagram showing a ring-shaped kinetic inductor tuned based on an applied flux.

FIG. 12 is a flowchart illustrating a method to switch a range of allowable frequencies transmitted across a tunable filter.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

### Hybrid Computing System

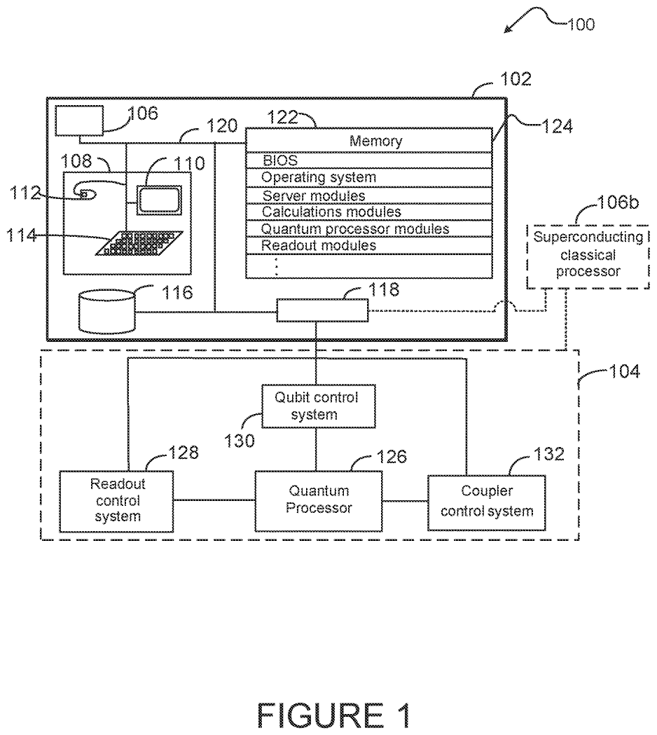

FIG. 1 illustrates a computing system 100 that advantageously employs one or more tunable filters and/or tunable inductors as described herein, according to at least one illustrated implementation. The computing system 100 comprises a digital computer 102. The example digital computer 102 includes one or more digital processors 106 that may be used to perform classical digital processing tasks. Digital computer 102 may further include at least one system memory 122, and at least one system bus 120 that couples various system components, including system memory 122 to digital processor(s) 106. System memory 122 may store one or more sets of processor-executable instructions, which may be referred to as modules 124.

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, digital processor(s) 106 of computing system 100 can optionally include at least one superconducting classical processor 106b. At least one superconducting classical processor 106b may be one of: an adiabatic quantum flux parametron (AQFP) based processor or a rapid single flux quantum (RSFQ) based processor, or any other suitable superconducting classical processor known in the art.

Superconducting classical processor 106b may include at least one superconducting integrated circuit, which includes at least one component consisting of one or more materials that superconduct at and below respective critical temperatures. Superconducting classical processor 106b may be located in a cryogenic environment, which may be provided by a dilution refrigerator. This may cryogenically cool superconducting classical processor 106b to at least the critical temperature, such that superconducting behavior of the at least one superconducting integrated circuit can be realized.

In some implementations, superconducting classical processor 106b may be arranged as a separate entity from, but communicatively coupled to, digital computer 102. In FIG. 1, digital computer 102 is shown to be communicatively coupled to superconducting classical processor 106b via, for instance, a controller 118. In such implementations, superconducting classical processor 106b may perform computations at the instruction of digital computer 102.

Although not shown in FIG. 1, superconducting classical processor 106b may alternatively be included as part of digital computer 102, and may communicate with other components of the digital computer 102 in the same manner as other digital processors of digital processor(s) 106.

In some implementations, superconducting classical processor 106b may additionally or instead be communicatively coupled to analog computer 104. Superconducting classical processor 106b may instruct analog computer 104 to perform particular computations.

In some implementations, computing system 100 comprises an analog computer 104, which may include one or more quantum processors 126. Quantum processor 126 may include at least one superconducting integrated circuit. Digital computer 102 may communicate with analog computer 104 via, for instance, controller 118. Certain computations may be performed by analog computer 104 at the instruction of digital computer 102, as described in greater detail herein.

Digital computer 102 may include a user input/output subsystem 108. In some implementations, the user input/output subsystem includes one or more user input/output components such as a display 110, a mouse 112, and/or a keyboard 114.

System bus 120 may employ any known bus structures or architectures, including a memory bus with a memory controller, a peripheral bus, and a local bus. System memory 122 may include non-volatile memory, such as read-only memory (“ROM”), static random-access memory (“SRAM”), Flash NAND; and volatile memory such as random-access memory (“RAM”) (not shown).

Digital computer 102 may also include other non-transitory computer- or processor-readable storage media or non-volatile memory 116. Non-volatile memory 116 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 116 may communicate with digital processor(s) 106 via system bus 120 and may include appropriate interfaces or controllers 118 coupled to system bus 120. Non-volatile memory 116 may serve as long-term storage for processor- or computer-readable instructions, data structures, or other data (sometimes called program modules or modules 124) for digital computer 102.

Although digital computer 102 has been described as employing hard disks, optical disks and/or solid-state storage media, those skilled in the relevant art will appreciate that other types of non-transitory and non-volatile computer-readable media may be employed. Those skilled in the relevant art will appreciate that some computer architectures employ non-transitory volatile memory and non-transitory non-volatile memory. For example, data in volatile memory may be cached to non-volatile memory or a solid-state disk that employs integrated circuits to provide non-volatile memory.

Various processor- or computer-readable and/or executable instructions, data structures, or other data may be stored in system memory 122. For example, system memory 122 may store instructions for communicating with remote clients and scheduling use of resources including resources on the digital computer 102 and analog computer 104. Also, for example, system memory 122 may store at least one of processor executable instructions or data that, when executed by at least one processor, causes the at least one processor to execute the various algorithms to execute instructions. In some implementations system memory 122 may store processor- or computer-readable calculation instructions and/or data to perform pre-processing, co-processing, and post-processing to analog computer 104. System memory 122 may store a set of analog computer interface instructions to interact with analog computer 104. For example, the system memory 122 may store processor- or computer-readable instructions, data structures, or other data which, when executed by a processor or computer causes the processor(s) or computer(s) to execute one, more, or all of the acts of the methods described below.

Analog computer 104 may include at least one analog processor. Analog computer 104 may be provided in an isolated environment, for example, in an isolated environment that shields the internal elements of the quantum processor from heat, magnetic field, and other external noise. The isolated environment may include a refrigerator, for instance a dilution refrigerator, operable to cryogenically cool the analog processor, for example to temperature below approximately 1 K.

Analog computer 104 will be described below as including at least one superconducting quantum processor, such as quantum processor 126, and enabling quantum-based computing. However, this is not intended to be limiting.

Analog computer 104 may include programmable elements such as qubits, couplers, and other devices (also referred to herein as controllable devices). Qubits may be read out via readout control system 128. In some implementations, readout control system 128 can include a plurality of readout devices, each for reading out results of one or more assigned qubits. Readout results may be sent to other computer- or processor-readable instructions of digital computer 102. Qubits may be controlled via a qubit control system 130. Qubit control system 130 may include on-chip Digital to Analog Converters (DACs) and analog lines that are operable to apply a bias to a target device. Couplers that couple qubits may be controlled via a coupler control system 132. Coupler control system 132 may include tuning elements such as on-chip DACs and analog lines. Qubit control system 130 and coupler control system 132 may be used to implement a quantum annealing schedule as described herein on quantum processor 126. In accordance with the present disclosure, a quantum processor, such as quantum processor 126, may perform quantum annealing and/or adiabatic quantum computation. Examples of quantum processors are described in U.S. Pat. No. 7,533,068.

Alternatively, a quantum processor, such as quantum processor 126, may be a universal quantum computer, and may perform universal adiabatic quantum computing, or other forms of quantum computation such as gate model-based quantum computation.

### Tunable Resonator Filters

The present systems, methods, and apparatus relate to electrical filters and input/output (I/O) circuits for providing electrical signals in an environment having a temperature at or below a critical temperature of a material used to form a superconducting circuit within a superconducting processor. Such an environment can be a cryogenic environment, such as a cryogenic environment provided by a dilution refrigeration system. I/O lines can be used within a system to couple computing devices located in a room temperature environment to a superconducting processor located within a cryogenic environment. The I/O lines can be microwave signal paths (i.e., transmission lines) that provide sufficient bandwidth for high-speed processor operation while minimizing coupling to the external environment.

It may be advantageous to reduce the effects of room temperature noise and heating effects in the filters to preserve the integrity of electrical signals travelling to the superconducting processor, which may include at least one of: a superconducting quantum processor, such as quantum processor 126, and a superconducting classical processor, such as superconducting classical processor 106b of FIG. 1. In implementations where the superconducting processor is a superconducting quantum processor, the superconducting quantum processor may include a plurality of superconducting qubits. The superconducting quantum processor may be highly sensitive to noise and undesired signal components, which may negatively impact the ability of its superconducting qubits to realize desired quantum effects.

In some implementations, it can be particularly challenging type to mitigate noise arising from propagation of blackbody radiation along an I/O line. Blackbody radiation results from electromagnetic radiation with energy exceeding qubit thermal energy, which has the potential to excite qubits out of a ground state. This excitation can lead to computational errors by a superconducting processor, which may be most problematic during a calculation stage of an operation cycle of a superconducting processor.

An impact of environmental noise and noise arising from blackbody radiation can be reduced by filtration of out-of-band frequencies along an I/O line used to electrically couple a superconducting circuit, such as quantum processor 126 or the entire analog computer 104 of FIG. 1, to a computing device, such as digital computer 102 of FIG. 1. In some implementations, the I/O line may be used by digital computer 102 to communicate with a particular device within analog computer 104.

To communicate with the desired device within analog computer 104, Frequency Multiplexed Resonator (FMR) technology can be employed as at least a portion of readout control system 128 and/or qubit control system 130. FMR technology has applications in inputting data to, or reading data out from, a superconducting quantum processor, for example via one or more Quantum Flux Parametron (QFP) devices. In quantum computing, it is desirable that the structures and/or devices used to instruct operation of the superconducting quantum processor and to output measured states of the plurality of qubits are scalable to support a large numbers of qubits.

FMR technology can be leveraged to provide a readout system for a quantum processor. A plurality of resonators (herein also operable as detectors) can be communicatively coupled to a common transmission line and integrated through frequency domain multiplexing. Frequency domain multiplexing (FDM) is a technique in which a communication bandwidth is divided into a number of non-overlapping sub-bands, and each sub-band is used to carry a separate signal. Frequency domain multiplexing is also referred to in the present application as: “frequency multiplexing” and “frequency division multiplexing”. Through use of FMR technology, superconducting resonators of different resonant frequencies can read out states of multiple qubits within a superconducting quantum processor, and can share a common microwave transmission line using frequency domain multiplexing.

In some implementations, the superconducting resonators may form at least part of a superconducting flux storage device, such as one or more superconducting digital-to-analog converters (DACs) or flux DACs. Alternatively, the superconducting resonators may be arranged in communication with one or more superconducting DACs. The superconducting DAC can use resonator-addressing to communicate with a device having an address corresponding with a selected frequency sub-band. In some implementations, a superconducting control system and its operation may be as described in U.S. Patent Application Publication No. 20210350268A1, and a resonator-addressed superconducting readout system and its operation may be as described in U.S. Patent Application Publication No. 20210057631A1.

Superconducting resonators and/or superconducting DACs may be implemented as part of analog computer 104 of FIG. 1. More particularly, the superconducting resonators and/or superconducting DACs that implement the resonator-addressed superconducting control system can be included as part of an FMR control system, which can be implemented at least a portion of readout control system 128.

Through use of a resonator-addressed superconducting control system, a user can also provide an input condition to quantum processor 126 via one or more components of user input/output subsystem 108 to directly or indirectly determine quantum behavior of qubits within quantum processor 126 for determination of a solution to a given problem. For example, a user may provide: an input used by qubit control system 130 to inform behavior of one or more qubits; an input used by coupler control system 132 to inform behavior of one or more couplers; and/or an input used by other components of readout control system 128 to inform behavior of one or more readout lines (ex. I/O lines). Each device may be individually accessed via the resonator-addressed superconducting control system based at least on the frequency sub-band associated with a particular device.

Limitation of passable frequencies through an I/O line may be beneficial in the reduction of noise transmitted to a superconducting circuit and/or to provide a signal having a frequency associated with an address of a particular superconducting resonator to access a desired device within the superconducting circuit. The limitation of passable frequencies maybe implemented through passive elements such as: filters, attenuators, current dividers and/or lossy transmission lines. Other filtration solutions such as SQUID switches may also be employed.

To limit passable frequencies, each signal travelling along a microwave path of an I/O line may have a signal path that includes one or more of: a bandpass filter, a superconductive powder filter, and a switch located within a cryogenic environment. Each of these components can be electrically coupled to one another by coaxial cables to form an I/O chain, which may then be electrically coupled to the superconducting circuit via an additional coaxial cable. Each of these coaxial cables can comprise one or more materials that exhibit superconductive behavior at and below a respective critical temperature, such as: niobium, aluminum, tantalum, and niobium-titanium.

In one implementation, I/O lines may be coupled to a superconducting processor, such as quantum processor 126, and provide readout capabilities for devices operating in a bandwidth of 4 GHz to 8 GHZ, inclusive. It can be advantageous for the I/O lines to filter out radiation and other signals components having frequencies that lie outside the 4 GHZ-8 GHz bandwidth using the above-described filter chain. In some instances, this can improve the operation of the superconducting processor by reducing noise that may induce calculation errors, such that the superconducting processor can advantageously provide more precise solutions to problems solved thereon. Alternatively, filtration may be used to isolate a sub-band of the 4 GHZ-8 GHz range for accessing a particular superconducting resonator that is operable to transmit a signal to a particular device within an analog computer.

While integration of the above-described filtration chain in I/O lines may efficiently reduce noise with frequencies that lie outside the readout bandwidth and/or address a desired device via a resonator addressed by a superconducting DAC, these solutions may have limitations. For instance, passive filter or filter elements may dissipate a large amount of energy, which may result in cryostat heating and additional radiation emission. The above-described approaches disadvantageously require design specifications of the filters to be set prior to construction, and have limited flexibility following the fabrication of the I/O lines. Conversely, devices, systems, and methods described below advantageously provide selective modification of allowable frequencies through the filter chain, which can allow adjustment (e.g., by a user) to the passable frequency range after installation of I/O lines into a system. For instance, particular unanticipated artefacts or noise sources may be present in a system after installation or construction of the system. One might not be able to easily filter out frequencies associated with such artefacts and noise sources using inflexible filter components, requiring the filtration system to be re-designed and re-installed.

An inflexible filter design sets a static allowable range of frequencies having a static bandwidth. This might filter out signals within particular frequency sub-bands of the communication bandwidth from transmission through an I/O line to an analog computer, and therefore may limit the accessibility of devices within the analog computer. To access each device within the analog computer, unique I/O lines may be required for each frequency sub-band of the communication bandwidth. This may increase a number of cables required, and subsequently a number of components, a footprint, and a cost of the system.

The use of passive elements in I/O filtration systems may provide only a frequency-domain based response to a signal transmitted across the I/O line. In some implementations, it may be favorable for a filter to provide a time-domain based response to a signal. For instance, it may be beneficial to isolate an analog processor from an I/O line during certain stages of a processor operation cycle to limit blackbody radiation from reaching the analog processor while performing calculations. It may be also advantageous to switch an allowable passband of a filter to correspond to different frequency sub-bands of the communication bandwidth to choose which device to access at a particular time. Switches may be used to provide time-domain based switching or to mitigate some of the pitfalls of inflexible filter design.

U.S. Pat. No. 11,105,866 discloses a broadband switch used, for example, to dynamically connect and disconnect an analog processor from an I/O line in a time-dependent manner. The broadband switch is intended to isolate an analog processor from its environment to mitigate the effects of blackbody radiation during a calculation stage of its operation cycle, and to access a full dynamic range of signal frequencies during its programming and readout stages. However, this broadband switch is designed only for processor isolation, and a range of passable frequencies through the switch is not selectively tunable.

A tunable filtration solution can be provided as a time-domain based switchable element along an I/O line for coupling an analog computer located in a cryogenic environment to a computing device. The tunable filtration solution can advantageously allow selective adjustment of its filter response following its fabrication via one or more tunable resonators, each including a tunable inductive element. The selective adjustment can, for instance, be performed a user or technician, or be performed by an automated system. The union of filter responses of the tunable resonators can provide a passband of the tunable filtration solution, and this passband can be shifted as desired through simultaneous tuning of respective tunable inductive elements of the tunable resonators. In some implementations, the passband may be selectively shifted to transmit different frequency sub-bands of the communication bandwidth to a superconducting control system in the analog computer to selectively access different, desired devices. In some implementations, the passband may be selectively shifted outside of a communication bandwidth of the analog computer to disconnect the analog processor from the I/O line.

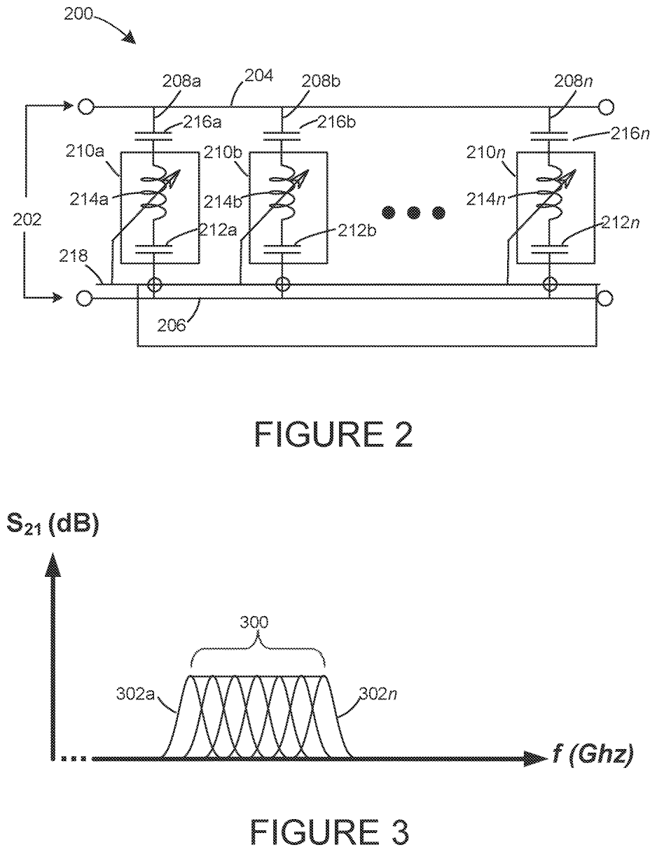

FIG. 2 shows a tunable band-pass filter 200 having a band-pass response, according to at least one illustrated implementation. The tunable band-pass filter 200 is arranged along a transmission line 202. Tunable band-pass filter 200 includes a plurality of shunt connections 208a, 208b-208n (three illustrated, collectively, 208) between a first conductor 204 and a second conductor 206 of transmission line 202. A tunable resonator 210a, 210b-210n (three illustrated, collectively, 210) is arranged along a respective one of shunt connections 208. Each one of tunable resonators 210 includes a respective resonator capacitor 212a, 212b-212n (three illustrated, collectively, 212) arranged in series with a respective tunable inductive element 214a, 214b-214n (three illustrated, collectively, 214). One or more bias lines 218 are electrically coupled to tunable inductive elements 214. Shunt capacitors 216a, 216b-216n (three illustrated, collectively, 216) are arranged in series with each tunable resonator 210 along each shunt connection 208.

Tunable band-pass filter 200 provides a band-pass response based on overlapping of frequency responses of individual ones of tunable resonators 210. Each one of tunable resonators 210 can have a unique resonant frequency (i.e., unique with respect to resonant frequencies of other ones of tunable resonators 210) determined by a value of its respective resonator capacitor 212 and a selected value of its tunable inductive element 214. Tunable resonators 210 can exhibit non-identical frequency responses to one another, such that the cumulative effect of tunable resonators 210 is a frequency band characterized by all frequencies that pass through any one of tunable resonators 210. To achieve this, the values of a plurality of resonator capacitors 212 may differ from one another and/or the values of each tunable inductive element 214 may be differently tuned from one another, such as tuned by a user and/or a calibration system.

The series arrangement of each one of resonator capacitors 212 and a respective one of tunable inductive elements 214 prevent frequencies below a resonator low cut-off frequency and frequencies exceeding a resonator high cut-off frequency from passing through. A lowest resonator low cut-off frequency and a highest resonator high cut-off frequency of tunable resonators 210 set the respective low and high cut-off frequencies of a passband of tunable band-pass filter 200.

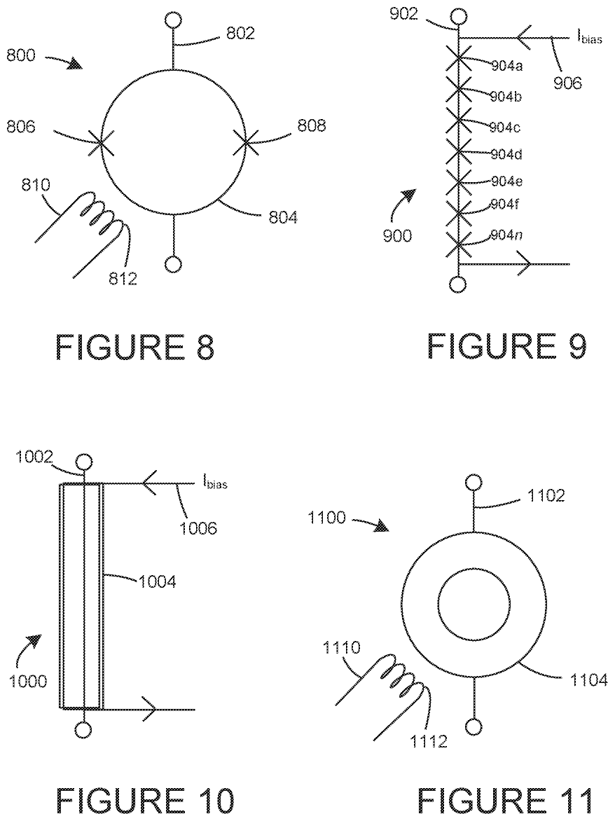

Bias line 218 is electrically coupled to tunable inductive elements 214 of tunable resonators 210. Bias line 218 is used to provide an electrical signal to tunable inductive elements 214 that changes respective inductance values. In one example, tunable inductive element 214 can optionally be a series of Josephson junctions. Bias line 218 can be used to apply a bias current to the Josephson junctions to set a desired inductance value. More detail regarding tunable inductive elements that can optionally be used within tunable band-pass filter 200 are described herein with respect to FIGS. 8, 9, 10, and 11.

A first end of bias line 218 is not shown in FIG. 2, but can optionally be electrically coupled to a component of analog computer 104 of FIG. 1. For instance, the signal provided by bias line 218 can be provided by readout control system 128 of FIG. 1.

In some implementations, there can optionally be one bias line 218 coupled to all tunable inductive elements 214. A single bias signal may be provided, thereby adjusting all tunable inductive elements 214 in a same manner. Alternatively, bias line 218 can optionally take the form of two or more bias lines, such that each bias line 218 is coupled to one or more tunable inductive elements 214. Use of separate bias lines allows for different signals to be provided to different tunable inductive elements 214, increasing a tuning granularity of the frequency response of tunable resonators 210.

In some implementations, first conductor 204 and second conductor 206 of transmission line 202 can be microwave lines embodied as twisted pairs or coaxial cables. At least a portion of the twisted pairs or coaxial cables located within a cryogenic environment can comprise one or more materials that exhibit superconducting behavior at and below a respective critical temperature. Tunable band-pass filter 200 can be arranged on transmission line 202 at a location within the cryogenic environment that has a temperature at or below the critical temperature of the material of transmission line 202 and circuit components of tunable band-pass filter 200.

In some implementations, a first end of transmission line 202 can be communicatively coupled to a computing device, such as component of digital computer 102 of FIG. 1. A second end of transmission line 202 can be communicatively coupled to a superconducting circuit, which may be a component of analog computer 104 of FIG. 1. In other implementations, transmission line 202 might not directly couple to the computing device and/or the superconducting circuit, but may communicatively couple to additional signal lines in communication with these elements. The arrangement in FIG. 2 shows only a small segment of transmission line 202, and does not preclude the inclusion of other filters or elements arranged along transmission line 202.

FIG. 3 is a graph plotting a frequency response of tunable band-pass filter 200 of FIG. 2. The graph plots the frequency of the filter response along the x-axis (measured in GHz), with respect to a S₂₁ coefficient of tunable band-pass filter 200 along the y-axis (measured in decibels). The S₂₁ coefficient is a magnitude of a forward transmission gain of tunable band-pass filter 200 along transmission line 202. The graph of FIG. 3 includes a passband 300 (also interchangeably referred to herein as: “combined passband”, “cumulative passband”, or “effective passband”), indicating the range of allowable frequencies transmitted across tunable band-pass filter 200. Passband 300 is formed by a plurality of frequency profiles 302a-302n (two called out, collectively, 302) that respectively correspond to the frequency response of each tunable resonator of tunable resonators 210.

Each frequency profile of frequency profiles 302 exhibits behavior of a band-pass filter. The union of allowable frequencies within frequency profiles 302 forms a plateau that determines a range of passband 300. A highest resonant frequency of all tunable resonators 210 is an overall high cut-off frequency of passband 300, and a lowest resonant frequency of all tunable resonators 210 is an overall low cut-off frequency of passband 300.

Plotted frequency profiles 302 indicate that each of tunable resonators 210 has a low-medium quality factor. A quality factor of a resonator can be expressed as a ratio between a resonant frequency and a 3 dB frequency of the resonator, which is the frequency at which a frequency of the resonator has decreased to half of its maximum power and marks a functional edge of its passband. The low-medium quality factor of tunable resonators 210 is graphically shown by frequency profiles 302 having passbands inclusive of a limited, but non-zero, range of frequencies.

Resonators having a high quality factor might be unsuitable for the present applications. A significantly greater number of resonators may be required to produce a tunable band-pass filter having a same passband 300 as the response of tunable band-pass filter 200 as shown in FIG. 3. This would require a greater number of circuit components, and subsequently increase the associated costs and footprint of the filter. As well, use of resonators having extremely high quality factors might prevent a plurality of resonators from having overlapping frequency profiles, and might not be shiftable in unison to operate as described herein.

On the contrary, designing tunable band-pass filter 200 using resonators with low quality factors might also be unsuitable for the present applications despite their wider passbands. The quality factor metric is also a ratio of power stored relative to power dissipated in a reactance and resistance of the resonator. As such, a frequency response of a resonator having a low quality factor is indicative of a large amount of energy dissipation, which may result in the introduction of a larger amount of error-inducing noise to the superconducting circuit. Consequently, it may be advantageous to use a larger number of low-moderate tunable resonators to achieve the desired passband while limiting the energy dissipation to a tolerable range for the desired application.

While resonators having any finite quality factor will dissipate thermal energy, losses can be limited by careful component selection. At least wiring and tunable inductive elements 214 of tunable resonators 210 can be formed of materials that exhibit superconducting behavior at and below a critical temperature, which is achieved in the cryogenic environment. Superconducting materials transmit energy more efficiently than non-superconducting materials, therefore dissipating significantly less thermal energy during signal transmission. For tunable band-pass filter 200 shown in FIG. 2 and the corresponding graph in FIG. 3, tunable resonator 210a is arranged closest to a first end of transmission line 202 and provides frequency profile 302a having a lowest resonant frequency. Subsequent tunable resonators 210b-210n are arranged increasingly further from the first end of transmission line 202 and respectively provide frequency profiles 302b-302n having increasingly higher resonant frequencies. This arrangement is only an example and is not intended to be limiting. Tunable resonators 210 are not required to be arranged on transmission line 202 based on their relative resonant frequency values, and instead can be ordered in any suitable manner.

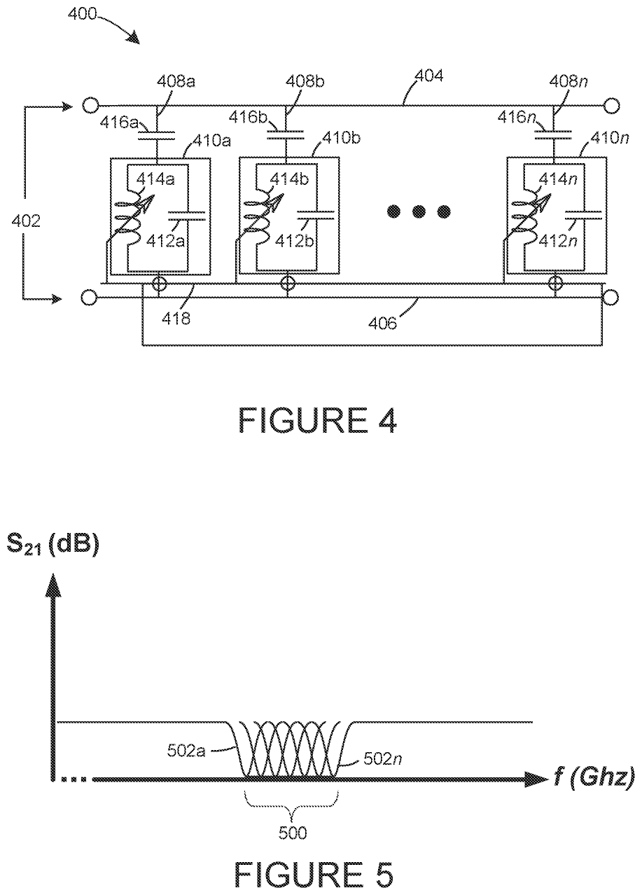

FIG. 4 shows a tunable band-stop filter 400 having a band-stop response, according to at least one implementation. Tunable band-stop filter 400 is arranged on a transmission line 402. Tunable band-stop filter 400 includes a plurality of shunt connections 408a, 408b-408n (three illustrated, collectively, 408) between a first conductor 404 and a second conductor 406 of transmission line 402. A tunable resonator 410a, 410b-410n (three illustrated, collectively, 410) is arranged along each one of shunt connections 408. Each one of tunable resonators 410 includes a respective resonator capacitor 412a, 412b-412n (three illustrated, collectively, 412) arranged in parallel with a respective tunable inductive element 414a, 414b-414n (three illustrated, collectively, 414). One or more bias lines 418 are electrically coupled to a plurality of tunable inductive elements 414. Shunt capacitors 416a, 416b-416n (three illustrated, collectively 416) are arranged in series with each one of tunable resonators 410 along each one of shunt connections 408.

Tunable band-stop filter 400 provides a band-stop response based on overlapping of frequency responses of individual ones of tunable resonators 410. Each one of tunable resonators 410 can advantageously be tuned to have a unique resonant frequency (i.e., unique with respect to resonant frequencies of other ones of tunable resonators 410) determined by a value of its respective one of resonator capacitors 412 and a selected value of its one of tunable inductive elements 414. Tunable resonators 410 can provide non-identical frequency responses to one another, such that a cumulative effect is characterized by all frequencies that are not passed through any of tunable resonators 410. To achieve this, the values of resonator capacitors 412 may differ from one another and/or the values of each one of tunable inductive elements 414 may be differently tuned, such as by a user and/or a calibration system.

The parallel arrangement of each one of resonator capacitors 412 and a corresponding one of tunable inductive elements 414 substantially prevents frequency values within a range between a resonator low cut-off frequency and a resonator high cut-off frequency from passing through.

One or more bias lines 418 may be arranged in a manner similar to bias line 218 of tunable band-pass filter 200 of FIG. 2, as described herein. Likewise, transmission line 402 may be embodied and arranged in a manner similar to transmission line 202 of tunable band-pass filter 200 of FIG. 2, as described herein.

FIG. 5 is a graph plotting a frequency response of tunable band-stop filter 400 of FIG. 4. The graph plots a frequency of the filter response along the x-axis (measured in GHz), with respect to a S₂₁ coefficient of tunable band-stop filter 400 along the y-axis (measured in decibels). The S₂₁ coefficient is the magnitude of the forward transmission gain of tunable band-stop filter 400 along transmission line 402. The graph of FIG. 5 includes a stopband 500 (also interchangeably referred to herein as: “combined stopband”, “cumulative stopband”, or “effective stopband”), which is indicative of a range of frequencies that are not transmitted across tunable band-stop filter 400. Stopband 500 is formed by a plurality of frequency profiles 502a-502n (only two called out, collectively, 502) that respectively correspond to a frequency response of each one of tunable resonators 410.

Each one of frequency profiles 502 exhibits the behavior of a band-stop filter having a stopband. A plateau formed by a union of unallowable frequencies within frequency profiles 502 determines a range of stopband 500. A highest resonant frequency of all tunable resonators 410 is an overall high cut-off frequency of stopband 500, and a lowest resonant frequency of all tunable resonators 410 is an overall low cut-off frequency of stopband 500. Use of the tunable filter within a system Tunable band-pass filter 200 of FIG. 2 and tunable band-stop filter 400 of FIG. 4 can be integrated into an I/O line used to communicatively couple a computing device to a superconducting circuit.

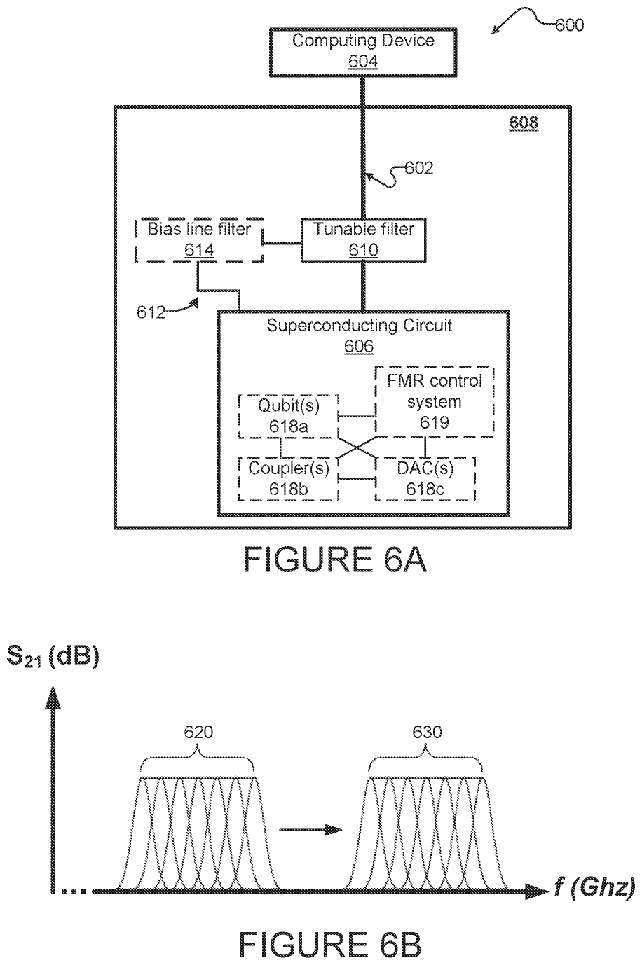

FIG. 6A shows a system 600 having a microwave path 602 including an integrated tunable filter operable to shift a passband of allowable frequencies, according to at least one implementation. Microwave path 602 communicatively couples a computing device 604 to a superconducting circuit 606. Computing device 604 can be arranged in a room temperature environment, and subsequently, a first end of microwave path 602 can also be located in the room temperature environment. Microwave path 602 then traverses through cryogenic environment 608, and a signal carried by microwave path 602 passes through a tunable filter 610 before terminating at superconducting circuit 606. A first end of a bias line 612 can be coupled to superconducting circuit 606, and a second end of bias line 612 can be coupled to tunable filter 610. In some implementations, a bias line filter 614 can optionally be arranged along bias line 612.

Tunable filter 610 of system 600 can be embodied as tunable band-pass filter 200 of FIG. 2 or tunable band-stop filter 400 of FIG. 4, which includes a plurality of tunable resonators 210 or 410 that set or configure a frequency response of tunable filter 610. More particularly, tunable resonators 210 or 410 include tunable inductive elements 214 or 414 that can be adjusted either individually or together through the application of a bias. The bias may be applied by the transmission of a signal from superconducting circuit 606 to inductive elements of tunable filter 610 via bias line 612, which can be embodied as bias line 218 or 418 of tunable band-pass filter 200 or tunable band-stop filter 402, respectively.

Superconducting circuit 606 can optionally take the form of analog computer 104 of FIG. 1, and the signal used to bias tunable filter 610 may originate from readout control system 128.

In implementations where superconducting circuit 606 includes a quantum processor, superconducting circuit 606 can optionally include a plurality of superconducting devices (collectively 618). Plurality of superconducting devices can include one or more of: qubit(s) 618a, coupler(s) 618b, and DAC(s) 618c, any of which can be communicatively coupled to one or more of other superconducting devices of plurality of superconducting devices 618. Superconducting circuit 606 can also optionally include FMR control system 619 having at least a plurality of superconducting resonators and/or DACs that comprise a portion of a resonator-addressed superconducting control system. Each resonator and/or DAC of FMR control system 619 may be communicatively coupled to one or more devices of plurality of devices 618.

Although system 600 is described below such that superconducting circuit 606 includes a quantum processor, this is not intended to be limiting. Superconducting circuit 606 can alternatively implement a classical superconducting processor, such as classical superconducting processor 106b of FIG. 1. The classical superconducting processor can be any one of an RSFQ, AQFP, or other classical superconducting processor known in the art.

Bias line filter 614 can optionally be implemented as a passive filter element, such as an inductive choke or kinetic inductor, and that allows tunable filter 400 to switch its passband at a desired switching speed.

Microwave path 602 can take the form of transmission line (e.g., transmission line 202 or 402), and can include coaxial cables or twisted pairs. At least the portion of microwave path 602 located within cryogenic environment 608 can comprise one or more materials that exhibits superconducting behavior at and below a respective critical temperature reached inside of cryogenic environment 608, which may reduce energy dissipation during signal transmission across microwave path 602.

Computing device 604 can be any electronic device located outside of cryogenic environment 608 that communicates with superconducting circuit 606. In some implementations, computing device 604 can optionally be digital computer 102 shown in FIG. 1. Computing device 604 can optionally be a component of digital computer 102, such as digital processor(s) 106 or part of user input/output subsystem 108. Computing device 604 is not limited to the example implementations described herein, and can be any suitable electronic device.

Although only one computing device 604 and microwave path 602 are shown in FIG. 6A, it will be understood that system 600 is not limited in this manner. Microwave path 602 may represent a plurality of microwave I/O lines that provide readout capabilities for a plurality of computing devices operating in a communication bandwidth of 4 GHZ-8 GHz. Each microwave I/O line can have a respective tunable filter 610, and in some implementations, a respective bias line 612 and bias line filter 614.

Cryogenic environment 608 can optionally be provided by a dilution refrigerator, such as a helium-3-helium-4 dilution refrigerator. In other implementations, other suitable technologies may be used to provide cryogenic environment 608. Examples of technologies used to provide cryogenic environments are described further in U.S. Pat. Nos. 9,134,047 and 10,378,803, U.S. Patent Application Publication No. 20200054961A1.

FIG. 6B is a graph illustrating a shift of the passband of allowable frequencies using system 600 of FIG. 6A. The graph of FIG. 6B plots a frequency response of tunable filter 610 (measured in GHz) on the x-axis and a transmission coefficient (measured in decibels) on the y-axis. In FIG. 6B, tunable filter 610 is embodied as tunable band-pass filter 200 of FIG. 2 and provides a passband of frequencies transmitted from computing device 604 through an I/O line along microwave path 602 to superconducting circuit 606.

A first passband 620 is shown on the graph of FIG. 6B, providing a frequency profile of tunable filter 610 used in a first operation mode in which tunable filter 610 allows a particular sub-band of a communication bandwidth of the I/O line to pass through. This may be used, for example, to access a particular one of plurality of superconducting devices 618, such as a qubit of qubit(s) 618a or a coupler of coupler(s) 618b, in superconducting circuit 606 via FMR control system 619. In some implementations, the frequency response of tunable filter 610 may be first passband 620 when no bias is applied. Like passband 300 shown in FIG. 3, first passband 620 corresponds to the union of frequency profiles of tunable resonators 210.

To operate system 600 in a second operation mode, a modified bias signal can be applied via bias line 612 to shift the range of signal frequencies that reach superconducting circuit 606. Specifically, a modified bias signal may be applied to tunable inductive elements 214 to shift the individual resonant frequencies of each of tunable resonators 210. This shifts first passband 620 along the x-axis of the graph of FIG. 6B to instead provide a second passband 630.

Second passband 630 is a frequency profile of tunable filter 610, in which a different sub-band of the communication bandwidth of the I/O lines is allowed to pass than the sub-band passed by tunable filter 610 in the first operation mode. After the shift into the second operation mode, microwave path 602 can be used to provide access to a different one of plurality of superconducting devices 618 in superconducting circuit 606 than the superconducting device accessed in the first operation mode.

In FIG. 6B, a size of the range of passable frequencies of the frequency profile of tunable filter 610 is a subset of the communication bandwidth of superconducting circuit 606 across the I/O lines. Accordingly, first passband 620 and second passband 630 have a same size of the range of passable frequencies. Tunable filter 610 operates in first operation mode when bias signals having a first value are applied to its tunable inductive elements via bias line 612. In the first operation mode, tunable filter 610 transmits frequencies therethrough of first passband 620, which comprises a first subset of frequencies of the communication bandwidth.

Tunable filter 610 operates in second operation mode when bias signals having a second value are applied to its tunable inductive elements via bias line 612. In the second operation mode, tunable filter 610 transmits frequencies therethrough of second passband 630, which comprises a second subset of frequencies of the communication bandwidth.

The second value of bias signals is non-identical to the first value of bias signals in order to modify the frequency response of tunable filter 610 such that second subset of frequencies includes a different portion of the communication bandwidth than the first subset of frequencies. The second value of bias signals is set between zero and a maximum value to selectively determine which frequencies belong to the second subset.

Although the graph shown in FIG. 6B only illustrates first passband 620 for operation in a first operation mode and second passband 630 for operation in a second operation mode, system 600 can optionally have more than two discrete operation modes and hence more than two discrete passbands. Any suitable number of operation modes may exist between an operation mode in which zero bias is applied to tunable filter 610 and in which a maximum bias signal is applied to tunable filter 610. If, for example, first passband 620 and second passband 630 are indicative of the application of zero bias and the maximum bias, then the frequency response graphed in FIG. 6B can include a shifted passband located at any point between these two passbands.

In an alternative implementation, tunable filter 610 can optionally be embodied as tunable band-stop filter 400 of FIG. 4. Tunable filter 610 can optionally have a first stopband operation mode, in which a first bias signal applied to tunable filter 610 prevents a particular range of frequencies from passing. The bias signal may be modified and applied via bias line 612 to tune resonant frequencies of tunable resonators 410, such that the frequency response of tunable filter 610 shifts to provide a second stopband operation mode.

Like in the implementation where tunable filter 610 is tunable band-pass filter 200, the implementation where tunable filter 610 is tunable band-stop filter 400 can optionally include either two discrete operation modes having zero bias and a maximum bias, or a plurality of operation modes in which intermediate biases are applied.

In some implementations, tunable filter 610 can optionally be used to rectify a signal transmitted across microwave path 602. For example, an alternating current (AC) signal may originate at computing device 604 and travel along an I/O line of microwave path 602. The AC signal may have equal positive and negative time-averaged amplitudes. As materials exhibiting superconductive behavior allow transmission of electrical energy with little to no impedance, it may be advantageous to convert the AC signal to a direct current (DC) signal when it is travelling through the I/O line and system 600 (e.g., superconducting circuit 606) in cryogenic environment 608.

To do so, tunable filter 610 can optionally be arranged as tunable band-pass filter 200 having a passband that is shifted at each half-cycle of the AC signal. A bias signal may be applied to tunable filter 610 via bias line 612 while the AC signal has a positive-valued amplitude. In one implementation, the bias signal may shift the passband of the filter response either into or outside of a frequency range of the AC signal. As such, tunable filter 610 may behave as a switch having an advantageously quick switching speed. Frequencies of the AC signal may be limited such that a time-averaged output signal of tunable filter 610 achieves a DC value.

In some implementations, use of tunable filter 610 as a rectifier alone might not provide a desirable DC signal, and other filters may be added to microwave path 602 following rectification. For example, capacitive filtration may be implemented to reduce ripple voltage of a DC output of tunable filter 610.

It may be beneficial to use tunable filter 610 to rectify an AC signal in system 600, as described above, to leverage the superconducting behavior of its components. This can advantageously reduce the amount of power dissipated during signal transmission, thereby reducing the effects of noise or artefacts that may negatively impact the operational precision of superconducting circuit 606. The time-domain controllability of a signal transmitted across bias line 612 enables quick and correct switching of the bandpass of tunable filter 610 to eliminate signal components having negative polarity.

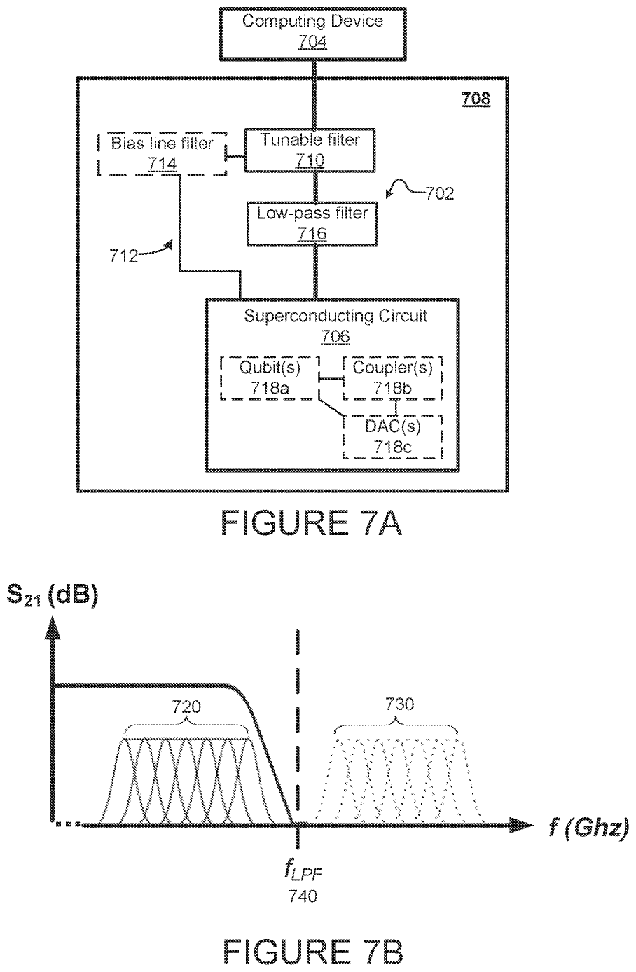

FIG. 7A shows a system 700 having a microwave path 702 including an integrated tunable filter 710 operable as a switch, according to at least one implementation. System 700 includes all the elements of system 600 of FIG. 6A; however, system 700 also includes a low-pass filter 716 arranged along microwave path 702. A first end of microwave path 702 is coupled to a computing device 704 at in a room temperature environment before traversing a cryogenic environment 708, in which a second end of microwave path 702 is coupled to a superconducting circuit 706. A signal carried by microwave path 702 can be filtered by tunable filter 710 arranged in series with low-pass filter 716. A first end of a bias line 712 can be coupled to superconducting device 706, and a second end of bias line 712 can be coupled to tunable filter 710. In some implementations, a bias line filter 714 can optionally be arranged along bias line 712.

Elements 702, 704, 706, 708, 710, and 712 can be embodied in the same manner as elements 602, 604, 606, 608, 610, and 612, respectively, of system 600.

Low-pass filter 716 can be implemented using any suitable analog circuit means, including passive and/or active elements. Additional signal lines can optionally be included in system 700 to supply inputs to the optional active components of low-pass filter 716 to provide a desired cut-off frequency. Low-pass filter 716 can optionally be constructed to have a static cut-off frequency and may include components having fixed values. Alternatively, low-pass filter 716 can optionally be constructed to be an additional tunable filter, such that its cut-off frequency may be controllably tuned through application of a bias signal to one or more of its components. In some implementations, the bias signal may be applied to low-pass filter 716 using bias line 712; alternatively, an additional bias line may be introduced to system 700.

A combination of low-pass filter 716 and tunable filter 710 can be operable as a switch. As signal components having frequencies below a low-pass cut-off frequency are passable through low-pass filter 716, the low-pass cut-off frequency can be selected based on an extremity of the operating passband of devices within the I/O chain (i.e., computing device 704 and superconducting circuit 706). Adjustment of a bias signal via bias line 712 can shift the frequencies passable through tunable filter 710 either in or out of a passband of low-pass filter 716, providing a switch that either substantially enables or substantially prevents signals from travelling across the filters along microwave path 702.

In some implementations, the described switch (formed by the combination of low-pass filter 716 and tunable filter 710) can be used to isolate a processor in superconducting circuit 706 during noise-sensitive stages of its operation cycle. When the processor is performing calculations, the switch can suppress signal transmission by shifting the passable frequency range of tunable filter 710 outside the passband of low-pass filter 716. As there is no required signal transmission during the calculation stage, suppression of signal content will not limit the functionality of the processor and may reduce undesirable noise originating upstream of the switch along microwave path 702. During the programming and readout stages of the operation cycle of the processor, the switch can enable communication between computing device 704 and superconducting circuit 706 by shifting the passable frequencies of tunable filter 710 within the passband of low-pass filter 716.

FIG. 7B is a graph illustrating the frequency response of a signal transmitted through system 700 of FIG. 7A when employed as a switch. The graph plots the frequency response of tunable filter 710 in series with low-pass filter 716, in which tunable filter 710 is embodied as tunable band-pass filter 200 of FIG. 2.

A frequency response of low-pass filter 716 is plotted on the graph having a low-pass passband and a low-pass cut-off frequency 740. The value of low-pass cut-off frequency 740 in FIG. 7B is slightly greater than 8 GHz, which may be a maximum device operation frequency of the I/O chain.

A first passband 720 is plotted on the graph of FIG. 7B, which can be the frequency response of tunable filter 710 in a first mode of operation. First passband 720 has a range spanning a communication bandwidth of the I/O chain (i.e., 4 GHZ-8 GHZ), and falls entirely below low-pass cut-off frequency 740 to enable signal transmission therethrough.

Modification of a bias signal via bias line 712 causes the switch to enter a second mode of operation by shifting the frequency response of tunable filter 710 to provide a second passband 730. As second passband 730 includes only frequencies exceeding low-pass cut-off frequency 740, all signal content in second passband 730 is suppressed by low-pass filter 716. Second passband 730 is shown using dashed lines on the graph of FIG. 7B to indicate that these frequencies are not transmitted across the entire switch.

In FIG. 7A, tunable filter 710 is arranged upstream (with respect to a direction of signal flow) of low-pass filter 716; however, this is not required. In an alternative implementation, tunable filter 710 can optionally be arranged downstream of low-pass filter 716.

Although tunable filter 710 is embodied as tunable band-pass filter 200 to provide the frequency response shown in FIG. 7B, tunable filter 710 can alternatively be implemented as tunable band-stop filter 400. In such an implementation, the low-pass cut-off frequency can be designed to be at or below the minimum operating frequency of the I/O chain (i.e., 4 GHz). In a first operation mode, tunable filter 710 can provide a first band-stop that suppresses frequencies below the low-pass cut-off frequency. This allows frequencies falling outside the first band-stop, including frequencies within the communication bandwidth of the I/O chain, to be transmitted across microwave path 702. A shift of the frequency response of tunable filter 710 into a second operation mode can provide a second band-stop that suppresses frequencies exceeding the low-pass cut-off frequency of low-pass filter 716, including frequencies within the communication bandwidth of the I/O chain.

In such an implementation, a stop-band of tunable filter 710 can optionally have a same size as the communication bandwidth of the I/O chain (ex., a stop-band may have a size of 4 GHZ). In the first band-stop operation mode, the first stop-band may suppress frequencies outside the communication bandwidth of the I/O chain, and may electrically couple computing device 704 to superconducting circuit 706 during programming and readout stages of an operation cycle of a processor located within superconducting circuit 706. In the second band-stop operation mode, the second stop-band may suppress all or substantially all frequencies in the 4 GHZ-8 GHz device communication bandwidth. This can cut off electrical signals originating from computing device 704 that have travelled across microwave path 702 to the switch, which may advantageously reduce the unwanted energy reaching the processor within superconducting circuit 706.

Although tunable filters 610 and 710 are shown to be arranged along microwave paths 602 and 702, respectively, on a transmission line, other arrangements can be realized. Tunable filter 610 can instead be integrated into superconducting circuit 606, along with the bias circuitry (i.e., bias line 612 and bias line filter 614) required for selective tuning of its frequency response. Likewise, the switch described above can be integrated into superconducting circuit 706 by arranging tunable filter 710, low-pass filter 716, and the relevant bias circuitry on-chip.

An arrangement having an integrated tunable filter can advantageously reduce the amount of noise that reaches highly-sensitive components of a superconducting circuit, such as a quantum processor. When arranged on a microwave line, the tunable filter or switch eliminates undesirable signal components originating upstream of the filter; however, additional noise may be introduced to the microwave line following filtration and may be propagated to the superconducting circuit. Arranging the tunable filter as part of the superconducting circuit can beneficially limit opportunities for noise introduction. Similarly, arranging the switching mechanism on-chip can further isolate the superconducting circuit from its environment when suppressing signal transmission.

### Tunable Inductive Elements

To shift the frequency response of the tunable filters described above, the resonant frequency values of each tunable resonator within the filter structure can be individually tuned. More particularly, an inductance value of the tunable inductive element of each tunable resonator can be tuned through the application of a bias signal. The tunable inductive elements can be one or more of the following structures: flux-biased DC SQUIDs, current-biased series arrays of Josephson junctions, current-biased strips of material having a high kinetic inductance, and flux-biased loops of material having a high kinetic inductance. These tunable inductive elements are illustrated in FIGS. 8, 9, 10, and 11 and are further described below.

FIG. 8 shows a DC SQUID 800 usable as a tunable inductor, according to at least one implementation. DC SQUID 800 includes a superconducting loop 804 on a superconducting line 802. Two Josephson junctions 806 and 808 are arranged along superconducting loop 804 integrated into the path thereof. A bias line 810 is arranged in near proximity to superconducting loop 804 to supply a bias current through a flux generating component 812, which provides magnetic flux to superconducting loop 804. The flux through superconducting loop 804 is quantized, providing an additional current within superconducting loop 804, which supplements existing current flowing through superconducting line 802. The current is divided around superconducting loop 804 and the flux is rounded to an integer number of flux quanta. Further details on magnetic flux-biased DC SQUIDs may be found in U.S. Pat. No. 11,105,866.

DC SQUID 800 can be used as one or more tunable inductive elements 214 or 414 of tunable band-pass filter 200 or tunable band-stop filter 400, respectively. Josephson junctions 806 and 808 of DC SQUID 800 are operable to act as an effective single junction, but having twice the critical current I_{C} as a single junction. Application of the flux bias by flux generating component 812 to superconducting loop 804 can lower the value of I_{C}, resulting in behavior resembling an in situ tunable Josephson junction. A Josephson inductance L_{J} of DC SQUID 800 can be mathematically described as follows:

$${L}_{J} = {ϕ}_{0} / ( 2 π \cdot {I}_{c} )$$

Here, the Josephson inductance L_{J} is a quotient of the initial magnetic flux quantum φ₀ in superconducting loop 804 with respect to the critical current I_{c} at an initial Josephson phase. As such, there is an inverse relationship between the critical current I_{c} and Josephson inductance Lⱼ realized by DC SQUID 800, which can strategically be used to tune one or more tunable inductive elements 214a-214n or 414a-414n and subsequently the frequency response of one or more respective tunable resonators 210 or 410.

Superconducting line 802 of DC SQUID 800 can be the wiring of a corresponding shunt connection 208 or 408. Bias line 810 can be bias line 218 or 418, and a second end of bias line 810 can be coupled to, for example, a control system within a superconducting circuit.

FIG. 9 shows a current-biased Josephson Junction array 900 usable as a tunable inductive element, according to at least one implementation. Current-biased Josephson Junction array 900 includes a series of Josephson junctions 904a, 904b, 904c, 904d, 904e, 904f-904n (seven illustrated, collectively, 904) arranged along a superconducting line 902. A first end of a bias line 906 is coupled to superconducting line 902 to provide a bias current I_{bias} that is applied to the series of Josephson junctions 904.

The following equations describe the behavior of the Josephson junctions 904:

$$I ( t ) = {I}_{c} sin ( φ ( t ) )$$

$$\frac{\partial φ}{\partial t} = \frac{2 eV ( t )}{ℏ}$$

where φ is the Josephson phase and I_{c} is the critical current of the Josephson junction. When a current is supplied externally, the phase must change to continue (to comply with the first equation) above, and this phase change in turn creates a voltage V(t) according to the second equation above. This voltage induced by the change in current makes the junction provide an effective inductance, which is also referred to as: “Josephson Inductance”. This Josephson inductance itself depends on the Josephson phase, which relates to the current according to the first equation above, so the current bias I_{bias} supplied will change the phase and thus the inductance supplied by the Josephson junction. By placing multiple such junctions in series, the bias current and resulting effect on inductance may be applied to all of the Josephson junctions of series of Josephson junctions 904 together, and the resulting inductances add together.

Series of Josephson junctions 904 can be used as one or more tunable inductive elements 214 or 414 of tunable band-pass filter 200 or tunable band-stop filter 400, respectively. Superconducting line 902 can be the wiring of a corresponding shunt connection 208 or 408. Bias line 906 can be bias line 218 or 418, and a second end of bias line 906 can be coupled to, for example, a control system within a superconducting circuit.

FIG. 10 shows a current-biased kinetic inductor 1000 usable as a tunable inductive element, according to at least one implementation. A kinetic inductor strip 1004 is arranged on a superconducting line 1002. A first end of a bias line 1006 is coupled to kinetic inductor strip 1004, which can be used to apply a bias current I_{bias} to kinetic inductor strip 1004.

Kinetic inductor strip 1004 can be used as one or more tunable inductive elements 214 or 414 of tunable band-pass filter 200 or tunable band-stop filter 400, respectively. Kinetic inductor strip 1004 may be formed of any material having a suitably high kinetic inductance value, such as niobium nitride (NbN) or titanium nitride (TiN). Superconducting line 1002 can be the wiring of a corresponding shunt connection 208 or 408. Bias line 1006 can be bias line 218 or 418, and a second end of bias line 1006 can be coupled to, for example, a control system within a superconducting circuit.

FIG. 11 shows a flux-biased kinetic inductor loop 1100 usable as a tunable inductive element, according to at least one implementation. A kinetic inductor loop 1104 is arranged on a superconducting line 1102. A bias line 1110 including a flux generating component 1112 is located in near proximity to kinetic inductor loop 1104. Bias line 1110 provides a biasing current through flux generating component 1112, which generates a magnetic flux to provide to kinetic inductor loop 1104.

Kinetic inductor loop 1104 can be used as one or more tunable inductive elements 214 or 414 of tunable band-pass filter 200 or tunable band-stop filter 400, respectively. Kinetic inductor loop 11004 may be formed of any material having a suitably high kinetic inductance value, such as NbN or TiN. Superconducting line 1102 can be the wiring of a corresponding shunt connection 208 or 408. Bias line 1110 can be bias line 218 or 418, and a second end of bias line 1110 can be coupled to, for example, a control system within a superconducting circuit.

A kinetic inductance L_{K} of kinetic inductor strip 1004 of FIG. 10 or kinetic inductor loop 1104 of FIG. 11 can be tuned to have a value such that it is on an edge of a region in which superconducting behavior is exhibited. The kinetic inductance L_{K} can be mathematically described as follows:

$${L}_{K} = \frac{\frac{1}{2} ( 2 {m}_{e} {v}^{2} ) ( {n}_{s} lA )}{\frac{1}{2} {I}^{2}} = ( \frac{{m}_{e}}{2 {n}_{s} {e}^{2}} ) ( \frac{l}{A} )$$

Here: mₑ is the electron mass and 2mₑ is the mass of a Cooper pair; v is the average Cooper pair velocity; nₛ is the density of Cooper pairs; l is the length of a wire, such as a length of kinetic inductor strip 1004 or a length of the material forming kinetic inductor loop 1104; A is a cross-sectional area of the wire; and, I is the current through the wire, which can also be expressed as I=2evnₛA. As kinetic inductance is inversely proportional to the density of Cooper pairs nₛ, increasing current/in kinetic inductor strip 1004 or kinetic inductor loop 1104 can increase the inductance realized by one or more tunable inductive elements 214 or 414. The value of current I can be modulated through application of a bias, such as a current applied to kinetic inductor strip 1004 via bias line 1006 or a current resulting from quantization of a flux applied to kinetic inductor loop 1104 via flux generating component 1112. In some implementation, this relationship can be leveraged to tune the frequency response of one or more respective tunable resonators 210 or 410.

### Methods of Shifting a Range of Passable Frequencies Using a Tunable Filter

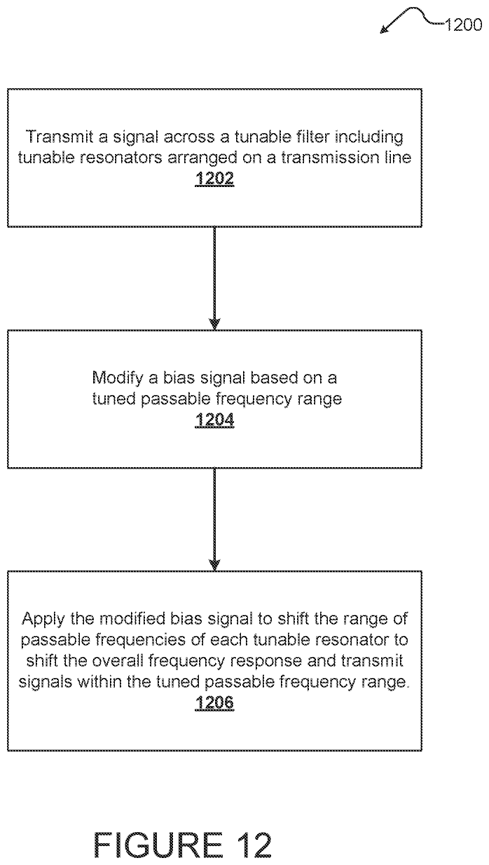

FIG. 12 is a flow diagram of an example method 1200 to shift a frequency range of signals travelling across a transmission line, according to at least one implementation. Method 1200 comprises acts: 1202, 1204, and, 1206; however, a person skilled in the art will understand that the number of acts illustrated is an example, and, in some implementations, certain acts may be omitted, further acts may be added, and/or the order of the acts may be changed.

At 1202, the signals are transmitted across a tunable filter arranged on the transmission line. The tunable filter can include a plurality of tunable resonators each having a tunable inductance and a fixed capacitance to provide respective resonator frequency responses, each with a range of passable frequencies. The tunable filter can have an overall frequency response determined by a union of the ranges of passable frequencies of the resonator frequency responses. The tunable filter and the transmission line can be comprised of one or more materials that exhibit superconducting behavior at and below respective critical temperatures.

In an implementation, tunable filter can be tunable filter 610 of FIG. 6A arranged along microwave path 602. The signals can be electrical signals originating from computing device 604 to instruct operation of superconducting circuit 606. Tunable filter 610 can optionally be tunable band-pass filter 200 of FIG. 2. Tunable filter 610 can comprise a material that is superconductive at a temperature achieved in cryogenic environment 608.

In an example, superconducting circuit 606 may be analog computer 104 and may include qubit control system 130. Prior to act 1202, tunable filter 610 may transmit signals within first passband 620 plotted in FIG. 6B. First passband 620 may have been set through selective tuning prior to the acts of method 1200 through the application of an initial bias signal, which may have a value between zero (i.e., no applied bias) and a maximum bias value. First passband 620 may correspond to a sub-band of the operating frequency range (i.e., a sub-band of the communication bandwidth) of the I/O chain, and may have been selected to access a particular device of plurality of superconducting devices 618 within superconducting circuit 606. For instance, the signal transmitted from computing device 604 may include, among other information, an instruction informing (e.g., setting, configuring) the behavior of a first qubit of qubit(s) 618a, and frequencies of first passband 620 may access the first qubit of qubit(s) 618a by communicating with a portion of qubit control system 130, such as FMR control system 619. Tunable filter 610 may filter out frequencies outside first passband 620 to limit communication to the first qubit.

In an alternative example, the tunable filter can optionally be tunable band-stop filter 400 of FIG. 4 and can have an overall frequency response corresponding to stopband 500 determined by a union of the ranges of passable frequencies of frequency profiles 502 of tunable resonators 410.

At 1204, a bias signal is modified based on a tuned passable frequency range. In an implementation, an instruction can be provided to superconducting circuit 606 by computing device 604 to tune a range of passable frequencies transmittable through tunable filter 610. Based on the instruction, superconducting circuit 606 can determine values of the tunable inductances needed to shift resonant frequency values of the tunable resonators into the tuned range of passable frequencies. Superconducting circuit 606 may then generate one or more bias signals that can adjust the values of the tunable inductances elements as needed. The instruction may be provided to superconducting circuit 606 on an ad-hoc basis by a user or the instruction may be programmed into computing device 604 to modify the bias signal at a particular time in a device operation cycle.

In an example, an initial bias signal applied to tunable filter 610 may provide first passband 620. Computing device 604 may instruct superconducting circuit 606 to shift the frequency response of tunable filter 610 from first passband 620 to second passband 630. Superconducting circuit 606 may calculate and subsequently generate one or more bias signals required to provide second passband 630.

At 1206, the modified bias signal is applied to each tunable inductance to shift the range of passable frequencies of each tunable resonator, such that the overall frequency response of the tunable filter shifts, and components of the signals within the tuned passable frequency range are transmitted.

In an implementation, the one or more bias signals generated by superconducting circuit 606 can be applied to tunable filter 610 via bias line 612. In an example where tunable filter 610 is tunable band-pass filter 200, the bias signals can be applied to tunable inductive elements 214 of tunable resonators 210. This shifts the frequency response of each tunable resonator 210, which consequently shifts the overall frequency response from first passband 620 to second passband 630. Following the application of the modified bias signal, components of signals having frequencies within second passband 630 can be transmitted from computing device 604 across tunable filter 610 to superconducting circuit 606.

In an example, the range of frequencies of second passband 630 may correspond to a second sub-band of the operating frequency range (i.e., the communication bandwidth) of the I/O chain. Frequencies of second passband 630 may access a second qubit of qubit(s) 618a in superconducting circuit 606 via frequency domain multiplexing by FMR control system 619, and signal content within second passband 630 may be used to provide instructions informing (e.g., setting, configuring) the behavior of the second qubit instead of the first qubit of qubit(s) 618a. Before the shift in the frequency response of tunable filter 610, the transmitted signal would be unable to modify behavior of the second qubit, as signals within its addressing range would have been filtered out.

In some implementations, the modified bias signal can optionally provide a modified bias current, and its application can tune a tunable inductive element embodied as the array of Josephson junctions of FIG. 9 or the strip of material having a high kinetic inductance value of FIG. 10. In other implementations, the modified bias signal can optionally provide a modified flux bias, and its application can tune a tunable inductive element embodied as the DC SQUID of FIG. 8 or the loop of material having a high kinetic inductance value of FIG. 11.

In another example, the tunable filter can optionally be tunable filter 710 of FIG. 7A arranged along microwave path 702. Application of a modified bias signal via bias line 712 can shift the overall frequency response of tunable filter 710. In an example, the tuned passable frequency range of filter 710 can be selected to prevent any signal transmission. As such, the modified bias signal can tune tunable filter 710 to have an overall frequency response of second passband 730, which would prevent signal transmission due to its frequencies exceeding low-pass cut-off frequency 740 of the switch comprised of tunable filter 710 and low-pass filter 716.

### CONCLUSIONS

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. Pat. Nos. 5,173,660, 7,533,068, 8,008,942, 8,190,548, 8,195,596, 8,421,053, 9,134,047, 10,378,803, and 11,105,866; U.S. patent application Ser. Nos. 16/663,723, 16/996,595, and 17/272,052; and, International Patent Publications No. WO2017192733A2 and WO2021231224A1.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A tunable filter to electrically couple to a transmission line, the tunable filter comprising:
a plurality of tunable resonators, each one of the plurality of tunable resonators comprising one or more materials that exhibit superconducting behavior at and below respective critical temperatures,
each tunable resonator of the plurality of tunable resonators comprising a respective tunable inductance and a respective fixed capacitance to provide a respective resonator frequency response having a respective range of passable frequencies, and
wherein the tunable filter has an overall resonator frequency response determined by a cumulative union of the ranges of passable frequencies of the resonator frequency responses of the plurality of tunable resonators, wherein the overall resonator frequency response is controllable by selective tuning of the tunable inductances.

2. The tunable filter of claim 1, wherein each resonator frequency response of a corresponding tunable resonator provides a respective range of passable frequencies that is non-identical to ranges of passable frequencies respectively provided by other tunable resonators of the plurality of tunable resonators.

3. The tunable filter of claim 1, further comprising one or more bias lines electrically coupled to the tunable inductances for transmission of respective bias signals to the tunable inductances to selectively tune their respective inductance values.

4. The tunable filter of claim 3, wherein a first end of the tunable filter is communicatively coupled to a superconducting device located in a cryogenic environment and a second end of the tunable filter is communicatively coupled to a computing device located in a region at room temperature,
wherein the tunable inductances are electrically coupled to the superconducting device via the one or more bias lines, and the bias signals transmitted to the tunable inductances are generated by the superconducting device.

5. The tunable filter of claim 4, wherein a size of the range of passable frequencies of the overall resonator frequency response is a subset of a communication bandwidth of the superconducting device,
the overall resonator frequency response of the tunable filter is operable to transmit frequencies in a first subset of the communication bandwidth when the bias signals applied to the tunable inductances have a first value, and
the overall resonator frequency response of the tunable filter is operable to transmit frequencies in a second subset of the communication bandwidth when the bias signals applied to the tunable inductances have a second value,
wherein the second value is non-identical to the first value, the second value is a value between zero and a maximum value, and the second value determines the frequencies belonging to the second subset.

6. The tunable filter of claim 5, wherein the tunable filter enables selective transmission one of a plurality of unique subsets of frequencies of the communication bandwidth of the superconducting device, each unique subset of frequencies operable to enable access to a corresponding one or more unique devices of a plurality of devices within the superconducting device, and
wherein each unique device of the plurality of device is one of: a qubit, a coupler, and a digital-to-analog converter (DAC).

7. The tunable filter of claim 1, wherein for each tunable resonator of the plurality of tunable resonators: the respective tunable inductance and the respective fixed capacitance are arranged in series with one another, each resonator frequency response includes a resonator passband, and the overall resonator frequency response is a bandpass response provided by a union of the resonator passbands.

8. The tunable filter of claim 1, wherein for each tunable resonator of the plurality of tunable resonators: the respective tunable inductance and the respective fixed capacitance are arranged in parallel with one another, each resonator frequency response includes a resonator stopband, and the overall resonator frequency response is a band-stop response provided by a union of the resonator stopbands.

9. The tunable filter of claim 1, further comprising a low-pass filter arranged in series with the plurality of tunable resonators, wherein the low-pass filter has a low-pass cut-off frequency, and, wherein a combination of the tunable filter and the low-pass filter form a switch having:
a first switch mode to transmit all frequency content of signals travelling through the switch, wherein all passable frequencies of the overall resonator frequency response fall below the low-pass cut-off frequency, and
a second switch mode to suppress all of the frequency content of the signals travelling through the switch, wherein all passable frequencies of the overall resonator frequency response exceed the low-pass cut-off frequency.

10. The tunable filter of claim 9, wherein:
a first end of the tunable filter is communicatively coupled to a superconducting device and a second end of the tunable filter is communicatively coupled to a computing device; and,
the tunable inductances are selectively tuned to switch between the first switch mode and the second switch mode based on a time-domain based bias signal corresponding to an operation cycle of the superconducting device, wherein:
in the first switch mode, the switch enables electrical communication between the superconducting device and the computing device, and
in the second switch mode, the switch electrically isolates the superconducting device during noise-sensitive stages of the operation cycle of the superconducting device.

11. The tunable filter of claim 1, wherein each of the tunable inductances is at least one of:
a magnetic flux-biased DC superconducting quantum interference device (SQUID);
a current-biased series array of Josephson junctions;
a current-biased strip of material having a high kinetic inductance value; and
a magnetic flux-biased loop of material having a high kinetic inductance value.

12. A method to shift a frequency range of signals that are transmittable across a transmission line comprising:
transmitting the signals across a tunable filter electrically coupled to the transmission line, wherein the tunable filter includes a plurality of tunable resonators each having a respective tunable inductance and a respective fixed capacitance to provide respective resonator frequency responses, the tunable filter having an overall resonator frequency response determined by a union of a ranges of passable frequencies of the resonator frequency responses, and the plurality of tunable resonators and the transmission line being comprised of one or more materials that exhibit superconducting behavior at and below respective critical temperatures;
modifying a bias signal based on a tuned passable frequency range; and
applying the modified bias signal to each tunable inductance to shift the range of passable frequencies of each tunable resonator, such that the overall resonator frequency response of the tunable filter shifts to enable transmission thereacross of components of the signals within the tuned passable frequency range.

13. The method of claim 12, wherein the applying the modified bias signal to each tunable inductance comprises: transmitting one or more modified bias signals across one or more bias lines that are electrically coupled to the tunable inductances to selectively tune their respective inductance values.

14. The method of claim 13, wherein a first end of the transmission line is electrically coupled to a superconducting device comprising a controller, and the modifying the bias signal comprises:
receiving, by the superconducting device, an instruction from a computing device coupled to a second end of the transmission line;
determining, by the controller of the superconducting device, the inductance values required of each tunable inductance to shift the range of passable frequencies of each tunable resonator such that the overall resonator frequency response of the tunable filter passes frequencies within the tuned passable frequency range; and
generating, by the controller of the superconducting device, the one or more modified bias signals required to tune the tunable inductances to the determined inductance values.

15. The method of claim 14, wherein the transmitting the signals across the tunable filter includes: transmitting one of a plurality of frequency subsets in a communication bandwidth of the superconducting device across the tunable filter,
wherein prior to the modifying the bias signal, the tunable filter receives a first bias signal to pass the components of the signals within a first frequency subset of the communication bandwidth, and
transmitting the components of the signals within the tuned passable frequency range across the tunable filter includes: passing the components of the signals within a second frequency subset of the communication bandwidth through the tunable filter.

16. The method of claim 15, wherein the transmitting one of the plurality of frequency subsets across the tunable filter further includes:
transmitting signal content having frequencies belonging to a unique frequency subset of the communication bandwidth, the unique frequency subset to enable access to a respective unique device in the superconducting device,
wherein each unique device is one of: a qubit, a coupler, and a digital-to-analog converter (DAC).

17. The method of claim 12, wherein the transmitting the signals across the tunable filter comprises: transmitting the signals across the plurality of tunable resonators, each tunable resonator having the respective tunable inductance and the respective fixed capacitance arranged in series with one another such that each resonator frequency response includes a resonator passband, wherein the overall resonator frequency response is a bandpass response provided by a union of the resonator passbands.

18. The method of claim 12, wherein the transmitting the signals across the tunable filter comprises: transmitting the signals across the plurality of tunable resonators, each tunable resonator having the respective tunable inductance and the respective capacitance arranged in parallel with one another such that each resonator frequency response includes a resonator stopband, and the overall resonator frequency response is a band-stop response provided by a union of the resonator stopbands.

19. The method of claim 12, the transmitting the signals across the tunable filter arranged on the transmission line further comprising: transmitting the signals across a low-pass filter arranged in series with the plurality of tunable resonators and having a low-pass cut-off frequency, wherein the tunable filter and the low-pass filter form a switch.

20. The method of claim 19, wherein:
prior to the modifying the bias signal, the transmitting the signals across the tunable filter includes operating the switch in a first switch mode, and
the applying the modified bias signal to each tunable inductance to shift the range of passable frequencies of each tunable resonator comprises: shifting the overall resonator frequency response of the tunable filter to operate the switch in a second switch mode, the second switch mode includes transmission of components of the signals within the tuned passable frequency range,
wherein the first switch mode and the second switch mode comprise different ones of:
transmitting all frequency content of the signals through the switch, wherein all passable frequencies of the overall resonator frequency response fall below the low-pass cut-off frequency, and
suppressing all frequency content of the signals through the switch, wherein all passable frequencies of the overall resonator frequency response exceed the low-pass cut-off frequency.

21. The method of claim 20, wherein a first end of the transmission line is electrically coupled to a superconducting device comprising a controller, and wherein the modifying the bias signal comprises:
generating, by the superconducting device, a time-domain based bias signal corresponding to an operating cycle of the superconducting device, wherein the time-domain based bias signal selectively tunes the overall frequency response of the tunable resonator to change between operation of the switch in the first switch mode and the second switch mode, and wherein:
operation of the switch in the first switch mode enables electrical communication between the superconducting device and a computing device, the computing device electrically coupled to a second end of the transmission line, and
operation of the switch in the second switch mode electrically isolates the superconducting device during noise-sensitive stages of the operation cycle of the superconducting device.

22. The method of claim 12, wherein the applying the modified bias signal to each tunable inductance includes at least one of:
applying a bias flux to at least one of: a DC superconducting quantum interference device (SQUID) and a strip of material having a high kinetic inductance value, and
applying a bias current to at least one of: a series array of Josephson junctions and a loop of material having a high kinetic inductance value.
